(19) United States
(12) Patent Application Publication
(10) Pub. No.: US 2010/0112776 A1
(43) Pub. Date: May 6, 2010

(54) APPARATUS FOR FORMING CONDUCTOR, METHOD FOR FORMING CONDUCTOR, AND METHOD FOR MANUFACTURING SEMICONDUCTOR DEVICE

(75) Inventors: Eiichi Kondoh, Kofu-shi (JP); Michiru Hirose, Kasugai-shi (JP); Hitoshi Tanaka, Kawasaki-shi (JP); Masayuki Satoh, Kasaoka-shi (JP); Hisashi Yano, Jyoyo-shi (JP); Masaki Yoshimaru, Hachioji-shi (JP)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: SEMICONDUCTOR TECHNOLOGY ACADEMIC RESEARCH CENTER, Yokohama-shi (JP)

(21) Appl. No.: 12/685,408

(22) Filed: Jan. 11, 2010

Related U.S. Application Data
(62) Division of application No. 11/845,615, filed on Aug. 27, 2007.

(30) Foreign Application Priority Data
Feb. 28, 2007 (JP) 2007-050362
Aug. 15, 2007 (JP) 2007-211877

(51) Int. Cl. H01L 21/02; B05D 5/12

(52) U.S. Cl. 438/386; 427/123; 257/E21.011

(57) ABSTRACT

A conductor forming apparatus includes a reaction container having housed therein a processing target on a surface of which a recess in which a conductor is to be provided is formed, and a process for providing the conductor in the recess being carried out inside the container after a supercritical fluid dissolved with a metal compound is supplied into the container, a supply device which supplies the fluid from an outside to the inside of the container, and a discharge device which discharges the fluid that is not submitted for the process from the inside to the outside of the container, wherein while an amount of the fluid in the container is adjusted by continuously supplying the fluid into the container by the supply device and continuously discharging the fluid that is not submitted for the process to the outside of the container by the discharge device.

### CROSS-REFERENCE TO RELATED APPLICATIONS

This application is based upon and claims the benefit of priority from prior Japanese Patent Applications No. 2007-050362, filed Feb. 28, 2007; and No. 2007-211877, filed Aug. 15, 2007, the entire contents of both of which are incorporated herein by reference.

### BACKGROUND OF THE INVENTION

1. Field of the Invention

The present invention relates to a technique of providing a conductor in a recess, and particularly to a conductor forming method and apparatus for providing a conductor, by the use of a so-called supercritical fluid, inside a fine hole or groove with a high aspect ratio; and a semiconductor device manufacturing method for providing fine wires, plugs, electrodes and the like on a semiconductor substrate by means of the apparatus or method.

2. Description of the Related Art

Fine wires, plugs, electrodes and the like must be formed in order to form a fine structure such as an integrated circuit or a microelectronic element. For this purpose, a process is essentially mandatory for charging a conductor such as a metal in a groove for forming a wire and a hole for forming a plug, or alternatively, inside a fine recess with high aspect ratio such as a recess for forming an electrode. At present, in such an embedding process, for example, a method for embedding a metal thin film in a recess portion by the use of a vapor deposition technique, a plating technique, the CVD technique, or the PVD technique is generally used. On the other hand, in recent years, downsizing and high integration of a variety of electronic devices including semiconductor devices such as LSIs have progressed remarkably. In addition, in the near future, it will be necessary to form structures having a superfine dimension of 100 nm or less. However, each of the embedding methods described previously has already approached the limit of embedding properties, and it has been found extremely difficult to embed the inside of a superfine recess of 100 nm or less without a gap.

In order to overcome such a problem, lately, a method has been proposed for embedding a metal thin film in a recess by the use of a so-called supercritical fluid. Such a technique is disclosed in, for example, Clean Technology 2004. 6, Japan Industrial Publishing Co., Ltd. (2004), pp. 55-58, or Semiconductor FPD World 2004. 8, pp. 44-47.

A supercritical fluid generally denotes a high-density fluid in a state in which a gas (gas phase) and a liquid (liquid phase) cannot be discriminated from each other. For example, in the case of carbon dioxide (CO₂), a supercritical fluid is obtained at a pressure of about 7.4 MPa and at a temperature of about 31° C. or more. A supercritical fluid has a variety of features such as solvent capability or nano-level permeability. After an organic metal complex serving as a material for a metal thin film is dissolved in such a supercritical fluid, the dissolved complex is reacted with, for example, a gas-like reaction aid as required, and then, the metal is precipitated, whereby a metal thin film can be deposited. As a result, a metal thin film can be charged in a fine structure by utilizing the permeability or high density of a supercritical fluid. However, an embedding process using a supercritical fluid is generally carried out under high pressure, as described previously. Therefore, a material for a metal thin film is usually charged, in a state in which the material is dissolved in a supercritical fluid, in a sealing container having housed therein a member in which the metal thin film is to be embedded, and then, reaction is completed. A process carried out in such a closed atmosphere is also referred to as a batch process.

However, in the batch process described previously, there is a disadvantage that a container except a material inflow path is closed, and thus, a state of the inside of a reaction container during reaction is prone to be unstable, and controllability of film thickness and film quality of a metal thin film to be formed is poor. Specifically, in the batch process, it is difficult to control a variety of film forming parameters that contribute to film forming reaction such as a temperature, a pressure, a material concentration in a reaction container, or alternatively, concentrations of a variety of additives for helping film forming reaction. Therefore, in the batch process, it is difficult to set in a desired state the film thickness or film quality of a metal thin film formed in the reaction container. In addition, there is also a disadvantage that continuous supply of material into a reaction container and continuous deposition of a metal thin film onto a film-formed member are principally limited because the capacity of the reaction container does not change, and an upper limit is forcibly set also for the film thickness of the metal thin film to be formed. Further, there is a disadvantage that, in the case where a solid material is used, the controllability of solubility relative to a supercritical fluid is difficult.

### BRIEF SUMMARY OF THE INVENTION

According to an aspect of the invention, there is provided a conductor forming apparatus, comprising: a reaction container having housed therein a processing target on a surface of which at least one recess in which a conductor is to be provided is formed, and a process for providing the conductor in the recess being carried out inside the reaction container after a supercritical fluid dissolved with a metal compound including a metal serving as a material for the conductor is supplied to the inside of the reaction container; a supply device, the supply device supplying the supercritical fluid from an outside to the inside of the reaction container; and a discharge device, the discharge device discharging the supercritical fluid that is not submitted for the process from the inside to the outside of the reaction container, wherein while an amount of the supercritical fluid in the reaction container is adjusted by continuously supplying the supercritical fluid to the inside of the reaction container by means of the supply device and continuously discharging the supercritical fluid that is not submitted for the process to the outside of the reaction container by means of the discharge device, the metal compound dissolved in the supercritical fluid is introduced in the recess in contact with the surface of the processing target, the metal compound introduced in the recess is aggregated in the recess, thereby precipitating the metal from the metal compound, and further, the conductor is provided in the recess by solidifying the metal precipitated in the recess.

According to another aspect of the invention, there is provided a conductor forming method comprising: to a processing target on a surface of which at least one recess in which a conductor to be provided is formed, continuously supplying a supercritical fluid dissolved with a metal compound including a metal serving as a material for the conductor, and continuously eliminating from a periphery of the processing target the supercritical fluid that is not submitted for a process for providing the conductor in the recess, thereby adjusting an amount of the supercritical fluid around the processing target; selectively introducing in the recess the metal compound dissolved in the supercritical fluid in contact with the surface of the processing target and aggregating in the recess the metal compound introduced into the recess to precipitate the metal from the metal compound; and solidifying the metal precipitated in the recess, thereby providing the conductor in the recess.

According to still another aspect of the invention, there is provided a manufacturing method for a semiconductor device comprising: to a semiconductor substrate on which at least one recess, in which a conductor is provided, is formed on a surface of at least one of a substrate main body and an insulation film provided above the substrate main body, continuously supplying a supercritical fluid dissolved with a metal compound including a metal serving as a material for the conductor and continuously eliminating from a periphery of the semiconductor substrate the supercritical fluid that is not submitted for a process for providing the conductor in the recess, thereby adjusting an amount of the supercritical fluid at the periphery of the semiconductor substrate; selectively introducing in the recess the metal compound dissolved in the supercritical fluid in contact with a surface of the semiconductor substrate and aggregating in the recess the metal compound introduced in the recess to precipitate the metal from the metal compound; and providing the conductor in the recess by solidifying the metal precipitated in the recess.

### BRIEF DESCRIPTION OF THE SEVERAL VIEWS OF THE DRAWING

FIG. 1 is a block diagram schematically depicting an apparatus for forming a conductor according to a first embodiment;

FIG. 2 is a sectional view schematically depicting an inside of a reaction container, with which the apparatus for forming a conductor shown in FIG. 1 is provided;

FIG. 3 is a sectional view schematically depicting an inside of a material supply device, with which the apparatus for forming a conductor shown in FIG. 1 is provided;

FIG. 4 is a view graphically depicting a condition for selecting an auxiliary solvent according to the first embodiment;

FIG. 5 is a view graphically depicting a condition for selecting an auxiliary solvent according to the first embodiment;

FIG. 6 is a view graphically depicting a condition for selecting an auxiliary solvent according to the first embodiment;

FIGS. 7A, 7B, 7C, and 7D are sectional views each showing a method for forming a conductor according to the first embodiment;

FIG. 8 is a sectional view showing the method for forming a conductor according to the first embodiment;

FIG. 9 is a sectional view schematically depicting a modified example of the apparatus for forming a conductor shown in FIG. 1;

FIG. 10 is a sectional view showing, by use of an SEM photograph, a structure of the vicinity of a conductor made of Cu, which is formed by a method for forming a conductor according to a second embodiment;

FIGS. 11A and 11B are sectional views each showing, by use of an SEM photograph, a structure of the vicinity of a conductor made of Cu, which is formed by a method for forming a conductor according to a third embodiment;

FIGS. 12A and 12B are sectional views each showing, by use of an SEM photograph, a structure of the vicinity of a conductor made of Cu, which is formed by the method for forming a conductor according to the third embodiment;

FIG. 13 is a view showing how to check film thickness of a conductor made of Cu, which is formed by the method for forming a conductor according to the third embodiment;

FIG. 14 is a view graphically depicting, for each film forming condition, the film thickness of the conductor made of Cu, which is checked by the method shown in FIG. 13;

FIG. 15 is a view schematically and graphically depicting a concentration distribution of materials for a conductor in a reaction container in the method for forming a conductor according to the third embodiment;

FIG. 16 is a photograph of a consumption state of a material for conductors in each state before and after carrying out the method for forming a conductor according to the third embodiment;

FIG. 17 is a view graphically depicting, by the presence or absence of auxiliary solvent and by type of auxiliary solvent, the size of enthalpy when a supercritical fluid flows into a reaction container in the method for forming a conductor according to the third embodiment;

FIG. 18 is a view schematically depicting part of an apparatus for forming a conductor according to a fourth embodiment;

FIG. 19 is a view graphically depicting a relationship between a temperature in a pre-heat chamber and a temperature in a reaction container, of the apparatus for forming a conductor shown in FIG. 18;

FIG. 20 is a view showing in a table, a processing condition when conductors are formed by the method for forming a conductor according to the fourth embodiment and a processing condition when conductors are formed by the method for forming a conductor according to Comparative Example relative to the fourth embodiment;

FIGS. 21A and 21B are views each graphically depicting a relationship between a distance and film thickness from an inlet of a reaction container when Cu-films have been formed under the processing conditions, each of which is described in the table shown in FIG. 20;

FIGS. 22A, 22B, and 22C are sectional views each showing, by the use of an SEM photograph, a film-forming situation in a predetermined location in a reaction container when a Cu-film has been formed under processing condition II among the processing conditions described in the table shown in FIG. 20;

FIGS. 23A, 23B, and 23C are sectional views each showing, by the use of an SEM photograph, a film-forming situation in a predetermined location in a reaction container when a Cu-film has been formed under processing condition V among the processing conditions described in the table shown in FIG. 20;

FIG. 24 is a perspective view showing, by the use of an SEM photograph, a structure of the vicinity of a conductor made of Ru, which is formed by a method for forming a conductor according to a fifth embodiment;

FIG. 25 is a sectional view showing, by the use of a magnified SEM photograph, a structure of the vicinity of the conductor made of Ru shown in FIG. 24;

FIG. 26 is a sectional view showing a method for manufacturing a semiconductor device according to a sixth embodiment;

FIGS. 27A and 27B are sectional views each showing a method for manufacturing a semiconductor device according to a seventh embodiment;

FIG. 28 is a sectional view showing the method for manufacturing a semiconductor device according to the seventh embodiment; and

FIG. 29 is a sectional view showing a method for forming a conductor according to an eighth embodiment.

### DETAILED DESCRIPTION OF THE INVENTION

Hereinafter, embodiments according to the present invention will be described with reference to the accompanying drawings.

### First Embodiment

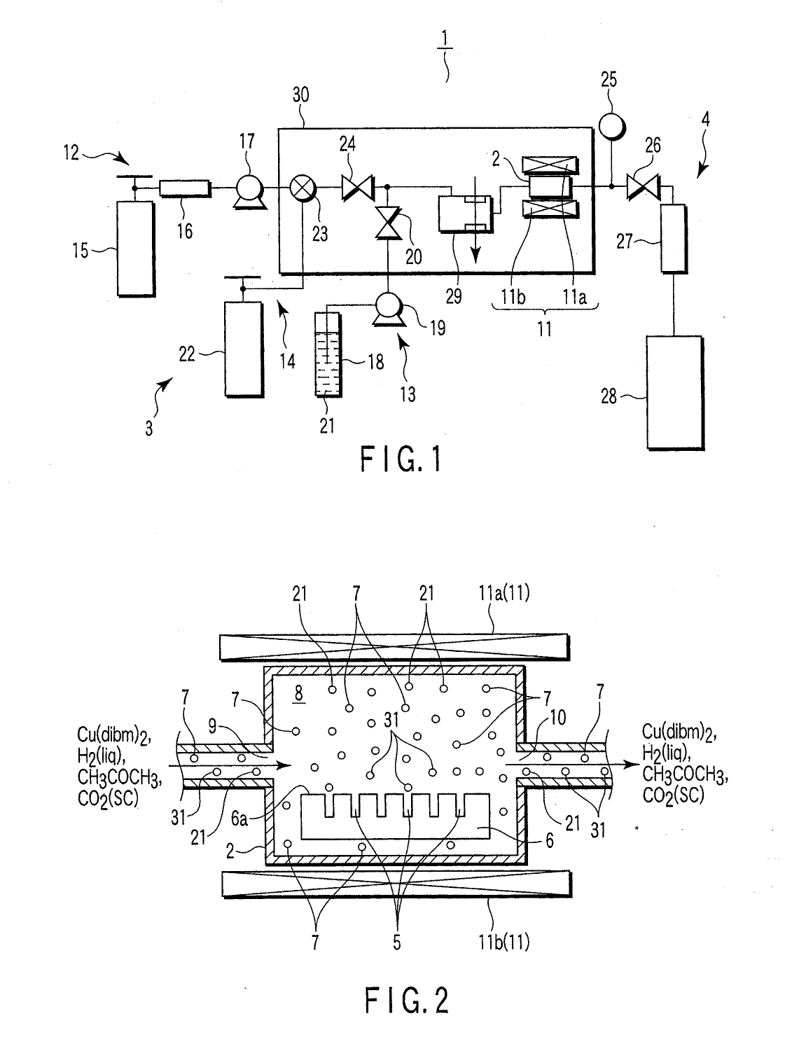

First, a first embodiment according to the present invention will be described with reference to FIGS. 1 to 9. In the present embodiment, a description will be given with respect to a technique of preferentially providing a conductor inside a fine recess with high aspect ratio by the use of a so-called supercritical fluid that is a kind of fluid in which a gas and a liquid cannot be discriminated from each other. Hereinafter, a description will be given specifically and in detail.

First, a conductor forming apparatus 1 according to the present embodiment will be described with reference to FIGS. 1 to 3.

As shown in FIG. 1, the conductor forming apparatus 1 is roughly composed of constituent elements such as a reaction container 2, a supply device 3, and a discharge device 4.

As shown in FIG. 2, a processing target 6 is housed inside the reaction container 2. A plurality of fine recesses 5 with high aspect ratio, in which conductors 33 described later are to be provided, have been formed on a surface 6a of the processing target 6. The processing target 6 is disposed, in a posture in which each of the recesses 5 has been oriented upwardly, on a processing target support (not shown) provided inside the pressure-resistant reaction container 2. In addition, a supercritical fluid 8, in which a metal compound 7 including a metal 32 serving as a material for the conductor 33 is dissolved, is supplied from the supply device 3 to the inside of the reaction container 2. In this manner, a process is carried out for providing the conductor 33 in the recesses 5 by the use of the supercritical fluid 8 inside the reaction container 2. In the following description, this process is simply referred to as a process for forming a conductor.

A supercritical state is generally achieved under an environment whose pressure is higher than atmospheric pressure. Therefore, a pressure-resistant container having a structure with improved pressure resistance is used as the reaction container 2 to withstand such high pressure. In addition, a process for forming a conductor is generally achieved under an environment having a temperature higher than room temperature. Therefore, a hot-wall container with improved heat resistance and heat insulation is used as the reaction container 2 to withstand such a high temperature. In addition, a so-called tubular furnace container is used as the reaction container 2 so that the inside thereof is entirely uniformly heated. Although not shown, at the pressure-resistant reaction container 2, an observation window is provided for observing the inside of the container.

In addition, as indicated by the solid line arrow in FIG. 2, the supercritical fluid 8 to be supplied from the supply device 3 is supplied from the outside to the inside of the pressure-resistant reaction container 2 via a supply port 9. At the same time, the supercritical fluid 8 in the pressure-resistant reaction container 2 which is not submitted for a process for forming a conductor is discharged from the inside to the outside of the pressure-resistant reaction container 2 by means of the discharge device 4 via a discharge port 10 provided independently of the supply port 9, as indicated by the solid line arrow in FIG. 2 similarly. With such a construction, the supply of the metal compound 7 and supercritical fluid 8 into the pressure-resistant reaction container 2 and the discharge of the metal compound 7 and supercritical fluid 8 from the inside of the pressure-resistant reaction container 2, can be continuously carried out by the use of the supply device 3 and the discharge device 4.

In addition, it is preferable that the discharge port 10 be provided at the downstream side of the supply port 9 along the flow of the supercritical fluid 8 introduced into the pressure-resistant reaction container 2 through the supply port 9. More preferably, as shown in FIG. 2, the discharge port 10 may be provided so as to be positioned on one straight line relative to the supply port 9 along the flow of the supercritical fluid 8 introduced into the pressure-resistant reaction container 2 through the supply port 9. Further preferably, as shown in FIG. 2, the processing target 6 may be disposed at such a position that it does not exist on a straight line for connecting the supply port 9 and the discharge port 10 with each other. With such a construction, the supercritical fluid 8 can be made to flow smoothly into and out of the pressure-resistant reaction container 2 without a danger that the flow of the supercritical fluid 8 may be interrupted by the processing target 6. In this manner, the atmosphere in the reaction container 2 can be speedily and easily set in an entirely uniform state or can be set in a stable state. As a result, when a process for forming a conductor is carried out, its controllability can be improved.

In addition, as shown in FIGS. 1 and 2, a first temperature regulator 11 is provided at the periphery of the pressure-resistant reaction container 2. This regulator 11 is for controlling an internal temperature of the pressure-resistant reaction container 2 to a temperature such that a process for forming a conductor is easily progressed. The process for forming a conductor, as described previously, is generally achieved under an environment having a temperature higher than room temperature. Thus, as the first temperature regulator 11, for example, a mantle heater unit is used as a heating device for heating the inside of the pressure-resistant reaction container 2. The mantle heater unit 11 is composed of two heaters: an upper mantle heater 11a for heating the inside of the pressure-resistant reaction container 2 from above; and a lower mantle heater 11b for heating the inside of the pressure-resistant reaction container 2 from below. The upper mantle heater 11a and the lower mantle heater 11b are each actuated independently, so that the inside of the pressure-resistant reaction container 2 can be heated individually from the upper part or lower part thereof. For example, among the upper and lower mantle heaters 11a and 11b, only the upper mantle heater 11a is actuated periodically at predetermined intervals. Then, the inside of the pressure-resistant reaction container 2 is heated periodically and eccentrically at predetermined intervals from its upper side. As a result, the upper part inside the pressure-resistant reaction container 2 is periodically higher in temperature at predetermined intervals than its lower part, and then, temperature non-uniformity occurs at the inside of the pressure-resistant reaction container 2. If the internal temperature of the pressure-resistant reaction container 2 becomes periodically non-uniform at predetermined intervals, the temperature and pressure of the atmosphere in the pressure-resistant reaction container 2 also becomes periodically non-uniform at predetermined intervals. Then, convection occurs periodically at predetermined intervals with the atmosphere in the pressure-resistant reaction container 2, and a difference in density occurs periodically at predetermined intervals between the upper part and the lower part of the atmosphere in the pressure-resistant reaction container 2. In other words, a pulse-like fluctuation in density occurs in the atmosphere in the pressure-resistant reaction container 2. As a result, a pulse-like fluctuation can be caused to occur with the density of the supercritical fluid 8 supplied into the pressure-resistant reaction container 2.

If a fluctuation occurs in the density of the supercritical fluid 8, the solubility of the metal compound 7 as a solute to be dissolved in the supercritical fluid 8 as a solvent increases. Therefore, by periodically actuating only the upper mantle heater 5a at predetermined intervals, the concentration of the metal compound 7 in the pressure-resistant reaction container 2 can be substantially enhanced without increasing a supply quantity of the metal compound 7 from the supply device 3. As a result, when a process for forming a conductor is carried out, its controllability can be improved. Finally, wasteful consumption of the metal compound 7 is suppressed, so that material saving, energy saving, and cost saving can be promoted and an environmentally-friendly process can be achieved. Obviously, such a phenomenon can be achieved by intermittently actuating only the lower mantle heater 11b instead of only the upper mantle heater 11a. Alternatively, a similar phenomenon can be achieved by alternately and intermittently actuating the upper and lower mantle heaters 11a and 11b. In other words, by individually and intermittently actuating the upper and lower mantle heaters 11a and 11b, the state of the atmosphere in the pressure-resistant reaction container 2 is partially made non-uniform periodically at predetermined intervals, so that a pulse-like fluctuation in density can be caused to occur in the atmosphere in the pressure-resistant reaction container 2.

In contrast, if the upper and lower mantle heaters 11a and 11b both are actuated, the atmosphere in the pressure-resistant reaction container 2 is heated uniformly from the top and bottom of the container, so that heating non-uniformity hardly occurs. In other words, when the mantle heaters 11a and 11b both are actuated, the atmosphere in the pressure-resistant reaction container 2 is entirely uniformly heated, so that a pulse-like fluctuation hardly occurs in density thereof. In addition, by actuating both of the mantle heaters 11a and 11b, the temperature and pressure of the atmosphere in the pressure-resistant reaction container 2 can be entirely stabilized and maintained at a predetermined value.

In addition, as shown in FIG. 1, the supply device 3 is composed of constituent elements such as a supercritical fluid supply device 12, a material supply device 13, and a reaction promoter supply device 14. These supercritical fluid supply device 12, material supply device 13, and reaction promoter supply device 14 can be actuated respectively independently.

The supercritical fluid supply device 12 is composed of: a supercritical fluid reservoir device 15; a liquefying device 16; and a supercritical fluid delivery device 17. The supercritical fluid supply device 12 is provided at the most upstream part in the flow (flow passageway) of the supercritical fluid 8 of the conductor forming apparatus 1 from the supply device 3 to the discharge device 4 through the pressure-resistant reaction container 2. The supercritical fluid supply device 12 supplies the material for the supercritical fluid 8 to the pressure-resistant reaction container 2. Hereinafter, carbon dioxide (CO₂) is used as a material for the supercritical fluid 8. Carbon dioxide becomes the supercritical fluid 8 that is a kind of fluid, in which, under an atmosphere of about 31° C. and about 7.4 MPa, a gas phase (gas) and a liquid phase (liquid) cannot be discriminated from each other, the fluid having the properties of both the gas and liquid phases. The supercritical fluid 8 of carbon dioxide generally has the features as described below. First, the supercritical fluid of carbon dioxide has high density and strong dissolving power that are close to a liquid state, and acts as a solvent. Secondly, the supercritical fluid of carbon dioxide has high dispersion and low viscosity that are close to a gas state. Thirdly, the supercritical fluid of carbon dioxide has almost no surface tension. Fourthly, the supercritical fluid of carbon dioxide has a critical pressure and a critical temperature that are low when a gas or liquid state enters a supercritical state, and the gas or liquid state can be easily phase-changed to the supercritical fluid state. Fifthly, the supercritical fluid of carbon dioxide has dissolving capability. Sixthly, the supercritical fluid of carbon dioxide has nano-level permeability. Seventhly, carbon dioxide is stable, inexpensive in price, and low in cost. It is also high in recyclability, and has less environmental impact and the like in comparison with fluorine or the like.

Carbon dioxide is reserved in a substantially liquid state in a siphon-type cylinder 15 serving as a supercritical fluid reservoir device. Carbon dioxide taken out from the cylinder 15 is first cooled by means of a cooling device 16 serving as a liquefying device, and then, is substantially completely liquefied. Then, the liquefied carbon dioxide is pressure-increased by means of a supercritical fluid delivery pump 17 serving as a supercritical fluid delivery device, and then transported to the pressure-resistant reaction container 2. Here, the liquid carbon dioxide is pressure-increased to, for example, about 10 MPa, by using a high-pressure pump as the supercritical fluid delivery pump 17. The supercritical fluid supply device 12 made of such constituent elements can supply the supercritical fluid 8 of carbon dioxide continuously to the pressure-resistant reaction container 2. In the following description, carbon dioxide in a supercritical state is referred to as a supercritical CO₂ fluid (CO₂(SC)) 8, and is discriminated from a liquid carbon dioxide (CO₂ (liq)) or a gaseous carbon dioxide (CO₂ (gas)).

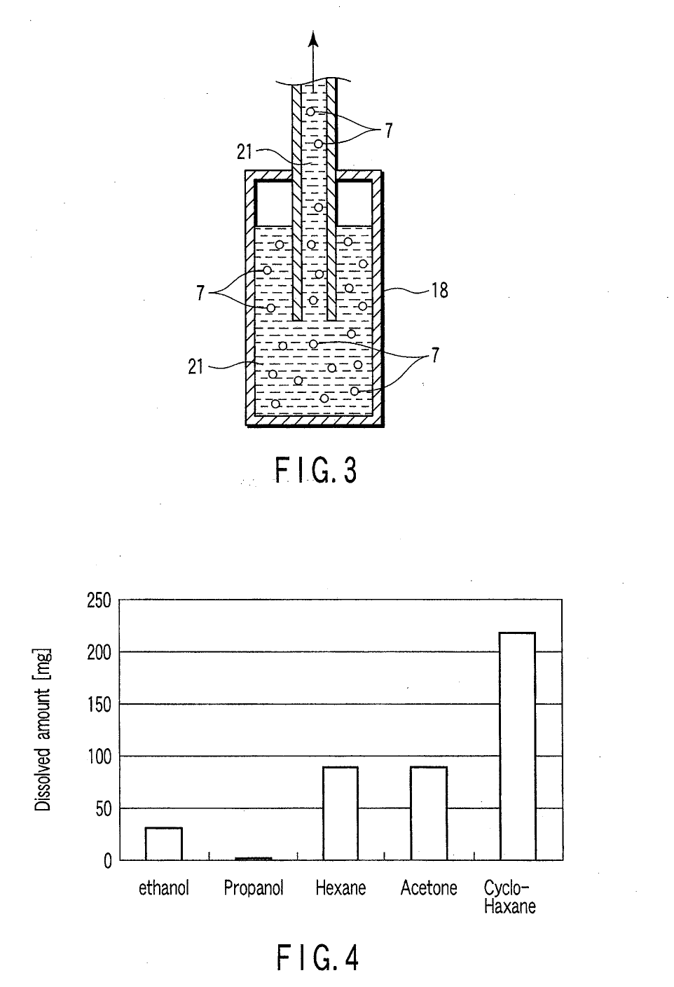

In addition, as shown in FIG. 1, a material supply device 13 is composed of: a material reservoir device 18; a material delivery device 19; and a material delivery valve 20. The material supply device 13 is connected at the more upstream side than the pressure-resistant reaction container 2 and at the more downstream side than the supercritical fluid supply device 12, to the flow passageway of the supercritical CO₂ fluid 8 of the conductor forming apparatus 1. The material supply device 13 dissolves and supplies in the supercritical CO₂ fluid 8 the metal compound 7 including a metal 32 serving as a material for a conductor 33. As described later, in the present embodiment, the conductor 33 is formed using copper (Cu). Hereinafter, a metal compound 7 containing copper is used as the metal compound 7. Specifically, diisobutyryl methanate copper (Cu(C₇H₁₅O₂)₂; Cu(dibm)₂) that is a kind of solid organic metal complex (precursor) is used. The diisobutyryl methanate copper 7 is reserved in a precursor reservoir 18 serving as a material reservoir device. More specifically, as shown in FIG. 3, the diisobutyryl methanate copper 7 is reserved in the precursor reservoir 18 in a state in which the copper is dissolved as a solute in an auxiliary solvent 21 that easily dissolves the diisobutyryl methanate copper 7 in the supercritical CO₂ fluid 8. Here, acetone (CH₃COCH₃) that is a kind of organic solvent is used as the auxiliary solvent 21.

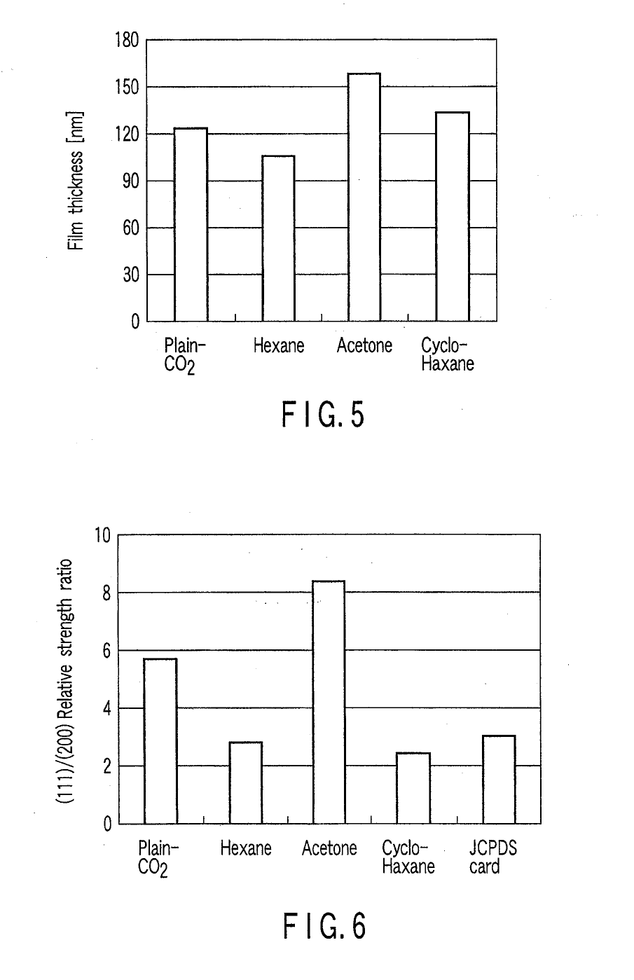

Here, a reason for selecting acetone as the auxiliary solvent 21 will be described with reference to FIGS. 4 to 6, which graphically depict results of experiments carried out by the inventors. First, FIG. 4 graphically depicts a result of measurement of a dissolved quantity of diisobutyryl methanate copper 7 in a variety of solvents of 1 ml. According to the graph shown in FIG. 4, it is found that cyclohexane is extremely high in the dissolved quantity of the diisobutyryl methanate copper 7. Acetone and hexane are the second highest. Next, FIG. 5 graphically depicts, for each of a variety of solvents, the film thickness of a Cu film in the case where the Cu film has been formed by means of the batch process described in the Description of the Related Art section. According to the graph shown in FIG. 5, it is found that the thickest Cu film can be obtained in the case where acetone is used as an auxiliary solvent. In addition, FIG. 6 graphically depicts, for each of a variety of solvents, (111)/(200) relative strength ratio of a Cu film in the case where the Cu film is formed by means of the batch process similarly. According to the graph shown in FIG. 6, it is found that a Cu film with the highest (111)/(200) relative strength ratio can be obtained in the case where acetone is used as the auxiliary solvent. In contrast, it is found that the (111)/(200) relative strength ratio of the Cu film is the lowest in the case where cyclohexane is used as the auxiliary solvent. It is generally known that the greater this (111)/(200) relative strength ratio is, the greater will be the reliability of a metal thin film used for an electronic device such as a semiconductor device.

Comprehensively judging from the results graphically depicted in FIGS. 4 to 6, the inventors selected acetone as the auxiliary solvent 21 suitable for the diisobutyryl methanate copper 7. While a specific and detailed illustrative description is not shown, according to the results of additional experiment further carried out by the inventors, it was found that, in the case where acetone is used as the auxiliary solvent 21, film forming speed and crystallinity can be enhanced in comparison with a case in which a substance other than acetone, such as hexane or cyclohexane, is used as the auxiliary solvent 21. In addition, acetone is cheaper than a substance such as hexane or cyclohexane. Therefore, by using acetone as the auxiliary solvent 21, the throughput of a process for forming a conductor and the quality and reliability of the conductor 33 formed by means of the process can be improved, and the cost associated with the process can be reduced or restricted. However, according to the results of additional experiment carried out by the inventors, it was verified that, if acetone is mixed by 10% or more in the supercritical CO₂ fluid 8 per unit volume, the supercritical CO₂ fluid 8 is separated into two phases, CO₂ and acetone and does not become a uniform phase, and then, the supercritical fluid is not obtained. Therefore, the inventors determined that a rate of acetone mixed in the supercritical CO₂ fluid 8 per unit volume is less than 10%.

The diisobutyryl methanate copper 7 reserved in the precursor reservoir 18, as indicated by the solid line arrow in FIG. 3, is first taken out from the precursor reservoir 18 in a state in which the copper is dissolved in acetone 21, by means of the material delivery pump 19 serving as a material delivery device. Next, as shown in FIG. 1, by opening the material delivery valve 20, the diisobutyryl methanate copper 7 and acetone 21 taken out from the precursor reservoir 18 are supplied into the supercritical CO₂ fluid 8 sent from the supercritical fluid supply device 12. In other words, the diisobutyryl methanate copper 7 is further dissolved in the supercritical CO₂ fluid 8 in a state in which the copper is dissolved in the acetone 21. In this manner, the diisobutyryl methanate copper 7 including copper 32 serving as a material for the conductor 33 is supplied toward the inside of the pressure-resistant reaction container 2 together with the supercritical CO₂ fluid 8. According to the material supply device 13 made of such a construction, the diisobutyryl methanate copper 7 dissolved in the acetone 21 can be continuously supplied into the supercritical CO₂ fluid 8. As a result, according to the material supply device 13, the diisobutyryl methanate copper 7 dissolved in the acetone 21 can be continuously supplied into a flow passageway (line) of the supercritical CO₂ fluid 8 of the conductor forming apparatus 1 such as the pressure-resistant reaction container 2. The material supply device 13 composed of the precursor 18, the material delivery pump 19, and the material delivery valve 20 is also referred to as a material adding unit.

In addition, the supply device 3 can stop supply of the diisobutyryl methanate copper 7 into the supercritical CO₂ fluid 8 by the material supply device 13 while supplying the supercritical CO₂ fluid 8 into the pressure-resistant reaction container 2 by means of the supercritical fluid supply device 12. In this manner, the supercritical CO₂ fluid 8 in which the diisobutyryl methanate copper 7 is not dissolved can be supplied into the pressure-resistant reaction container 2 instead of the supercritical CO₂ fluid 8 in which the diisobutyryl methanate copper 7 is dissolved. For this purpose, there is no need for the material supply device 13 to stop the material delivery pump 19 and the material delivery valve 20 together. It is sufficient as long as the material supply device 13 stops either one of the material delivery pump 19 and the material delivery valve 20. For example, by deactivating the material delivery pump 19 or completely closing the material delivery valve 20, the supercritical CO₂ fluid 8 containing no diisobutyryl methanate copper 7 can be supplied into the pressure-resistant reaction container 2. As a result, by adjusting output or operability of the material delivery pump 19 or adjusting the degree of opening of the material delivery valve 20, the quantity and concentration of the diisobutyryl methanate copper 7 or copper 32 in the pressure-resistant reaction container 2 can be set in a proper state.

In addition, as shown in FIG. 1, the reaction promoter supply device 14 is composed of a reaction promoter reservoir device 22 and a mixing unit 23. The reaction promoter supply device 14 is connected at the more upstream side than the material supply device 13 and at the more downstream side than the supercritical fluid supply device 12, to a flow passage way of the supercritical CO₂ fluid 8 of the conductor forming apparatus 1. In FIG. 1, although not shown, the reaction promoter supply device 14 supplies a reaction promoter 31, which promotes precipitation of the metal 32 from the metal compound 7, into the supercritical fluid 8. In the present embodiment, the reaction promoter supply device 14 supplies the reaction promoter 31, which promotes precipitation of the copper 32 from the diisobutyryl methanate copper 7, into the supercritical CO₂ fluid 8. Here, hydrogen (H₂) 31 is used as such a reaction promoter. The hydrogen 31 acts to reduce and precipitate the copper 32 included in the diisobutyryl methanate copper 7 dissolved in the supercritical CO₂ fluid 8.

An action (entrainer effect) of enhancing saturation solubility of the diisobutyryl methanate copper 7 relative to the supercritical CO₂ fluid 8 is also expected in the hydrogen 31. If the hydrogen 31 has this entrainer effect, by mixing the hydrogen 31 in the supercritical CO₂ fluid 8, the diisobutyryl methanate copper 7 can be excessively dissolved in the supercritical CO₂ fluid 8 in comparison with a case in which the hydrogen 31 is not mixed in the supercritical CO₂ fluid 8. The copper 32 included in the diisobutyryl methanate copper 7 excessively dissolved in the supercritical CO₂ fluid 8 is easily precipitated by excessive dissolving at least while the process for forming a conductor is in progress. Therefore, a time required for the step of embedding the inside of the recesses 5 with copper 32 can be expected to be shorter by mixing the hydrogen 31 into the supercritical CO₂ fluid 8. In other words, an effect of enhancing a throughput speed of the process for forming a conductor can be expected.

As shown in FIG. 1, the hydrogen 31 is reserved in a siphon-type cylinder 22 serving as a reaction promoter reservoir device. The hydrogen 31 taken out from the cylinder 22 is mixed in the supercritical CO₂ fluid 8 by means of the mixing unit 23 provided at a connection portion between the reaction promoter supply device 14 and a flow passageway of the supercritical CO₂ fluid 8 flowing from the supercritical fluid supply device 12 to the pressure-resistant reaction container 2. According to the reaction promoter supply device 14 having such a configuration, the hydrogen 31 can be continuously charged into the supercritical CO₂ fluid 8. As a result, according to the reaction promoter supply device 14, the hydrogen 31 can be continuously charged into a flow passageway (line) of the supercritical CO₂ fluid 8 of the conductor forming apparatus 1 including the pressure-resistant reaction container 2.

In addition, as described previously, the reaction promoter supply device 14 is connected to the flow passageway of the supercritical CO₂ fluid 8 at the more upstream side than the material supply device 13. Thus, the hydrogen 31 is mixed in the supercritical CO₂ fluid 8 before the diisobutyryl methanate copper 7 dissolved in the acetone 21 is dissolved in the supercritical CO₂ fluid 8. The quantity and concentration of the hydrogen 31 in the supercritical CO₂ fluid 8 can be appropriately set in a proper state by adjusting a mixing ratio of the hydrogen 31 relative to the supercritical CO₂ fluid 8 by means of the mixing unit 23. As a result, the solubility of the diisobutyryl methanate copper 7 in the supercritical CO₂ fluid 8 can be approximately set in a proper state by adjusting the quantity and concentration of the hydrogen 31 in the supercritical CO₂ fluid 8 by means of the mixing unit 23. For example, the charge of the hydrogen 31 into the supercritical CO₂ fluid 8 is stopped by completely closing the mixing unit 23. In this manner, the solubility of the diisobutyryl methanate copper 7 in the supercritical CO₂ fluid 8 can be reduced. In addition, the supercritical CO₂ fluid 8 containing no hydrogen 31 can be supplied into the pressure-resistant reaction container 2.

In addition, as shown in FIG. 1, in the flow passageway of the supercritical CO₂ fluid 8 of the conductor forming apparatus 1, a supercritical fluid delivery valve 24 is provided at the more upstream side than the material supply device 13 and at the more downstream side than the mixing unit 23. By opening the supercritical fluid delivery valve 24, the supercritical CO₂ fluid 8 or the supercritical CO₂ fluid 8 charged with the hydrogen 31 can be supplied to the pressure-resistant reaction container 2. In addition, by adjusting the degree of opening of the supercritical fluid delivery valve 24, the quantity of supply to the pressure-resistant reaction container 2 of the supercritical CO₂ fluid 8 or the supercritical CO₂ fluid 8 charged with the hydrogen 31 can be appropriately set in a proper state. As a result, as described previously, not only by adjusting the material delivery pump 19 and the material delivery valve 20 with which the material supply device 13 is provided, but also by adjusting the degree of opening of the supercritical fluid delivery valve 24, the concentration of the diisobutyryl methanate copper 7 or copper 32 in the pressure-resistant reaction container 2 can be appropriately set in a proper state.

In addition, as shown in FIG. 1, the discharge device 4 is composed of a pressure gauge 25, a pressure control valve 26, a pressure regulator 27, and a separator 28. The discharge device 4 is provided at the most downstream part of the downstream side of the pressure-resistant reaction container 2 in the flow passageway of the supercritical CO₂ fluid 8 of the conductor forming apparatus 1. The discharge device 4 discharges from the inside to the outside of the pressure-resistant reaction container 2 the supercritical CO₂ fluid 8 or the like that is not submitted for the process for forming a conductor. Specifically, a back pressure valve 26 serving as a pressure control valve is opened and a back pressure regulator (BPR) 27 serving as a pressure regulator is actuated. In this manner, among the flow passageways of the supercritical CO₂ fluid 8 of the conductor forming apparatus 1, the pressure of the flow passageway at the downstream side from the pressure-resistant reaction container 2 is set to be lower than an internal pressure of the pressure-resistant reaction container 2. As a result, the supercritical CO₂ fluid 8 or the like that is not submitted for the process for forming a conductor in the pressure-resistant reaction container 2 is discharged from the inside to the outside of the pressure-resistant reaction container 2. At this time, it is preferable that the pressure of the flow passageway at the downstream side from the pressure-resistant reaction container 2 should be automatically maintained in a proper state by means of the back pressure valve 26 and the back pressure regulator 27 while it is monitored by means of the pressure gauge (pressure sensor) 25.

In addition, the back pressure valve 26 and the back pressure regulator 27 serve to always control at a proper value, the pressure of the entire flow passageway of the supercritical CO₂ fluid 8 of the conductor forming apparatus 1 together with the supercritical fluid delivery pump 17, the material delivery pump 19, the material delivery valve 20, and the supercritical fluid delivery valve 24. In particular, the back pressure valve 26 and the back pressure regulator 27 serve to appropriately regulate and hold at a proper value, in accordance with the progress of the process for forming a conductor, the internal pressure of the pressure-resistant reaction container 2 while the process for forming a conductor is in progress, together with the supercritical fluid delivery pump 17, the material delivery pump 19, the material delivery valve 20, and the supercritical fluid delivery valve 24. In addition, obviously, the internal pressure of the pressure-resistant reaction container 2 while the process for forming a conductor is in progress can be stabilized and maintained at a predetermined value by adjusting the back pressure valve 26, the back pressure regulator 27, the supercritical fluid delivery pump 17, the material delivery pump 19, the material delivery valve 20, and the supercritical fluid delivery valve 24, respectively. By means of these constituent elements, the process for forming a conductor can be properly progressed.

Further, the back pressure valve 26 and the back pressure regulator 27, as in the upper and lower mantle heaters 11a and 11b described previously, can cause a pulse-like density fluctuation in an atmosphere in the pressure-resistant reaction container 2. For example, the back pressure valve 26 and the back pressure regulator 27 are actuated while the pressure of the flow passageway at the downstream side from the pressure-resistant reaction container 2 is monitored by means of the pressure sensor 25, so that the internal pressure of the pressure-resistant reaction container 2 periodically rises or falls within the range of about ±10% and at predetermined intervals. Then, the internal atmospheric pressure of the pressure-resistant reaction container 2 also periodically rises or falls within the range of about ±10% and at predetermined intervals, whereby the density of the atmosphere in the pressure-resistant reaction container 2 becomes periodically non-uniform in the range of about ±10% and at predetermined intervals. In other words, a pulse-like fluctuation can be caused to occur with the density of the atmosphere in the pressure-resistant reaction container 2. Specifically, a pulse-like fluctuation can be caused to occur with the density of the supercritical CO₂ fluid 8 containing the diisobutyryl methanate copper 7, acetone 21, and hydrogen 31 supplied into the pressure-resistant reaction container 2.

As a result, the concentration of the diisobutyryl methanate copper 7 in the pressure-resistant reaction container 2 can be substantially enhanced, or alternatively, the controllability of the process for forming a conductor can be improved, without increasing the quantity of supply of the metal compound 7 from the supply device 3. In addition, material saving, energy saving, and cost saving can be promoted while wasteful consumption of the diisobutyryl methanate copper 7 is restricted, and an environmentally-friendly process can be achieved. By operating the supercritical fluid delivery pump 17 and the supercritical fluid delivery valve 24 as well as the back pressure valve 26 and the back pressure regulator 27, obviously, a pulse-like density fluctuation can be caused to occur with the atmosphere in the pressure-resistant reaction container 2.

The supercritical CO₂ fluid 8 or the like discharged from the pressure-resistant reaction container 2 is delivered to the separator 28 provided at the downstream side of the back pressure regulator 27. In the separator 28, unreacted diisobutyryl methanate copper 7, which has not contributed to the process for forming a conductor and is contained in the supercritical CO₂ fluid 8, is re-collected. By measuring the concentration of the diisobutyryl methanate copper 7 re-collected by means of the separator 28, a use rate of a material in the process for forming a conductor using the conductor forming apparatus 1 can be obtained, as described later.

In addition, as shown in FIG. 1, in the flow passageway of the supercritical CO₂ fluid 8 of the conductor forming apparatus 1, a concentration detecting device 29 for detecting the concentration of the diisobutyryl methanate copper 7 dissolved in the supercritical CO₂ fluid 8 is further provided between the supply device 3 and the pressure-resistant reaction container 2. More specifically, a light absorption analyzing device (VIS) 29 serving as a concentration detecting device for optically detecting the concentration of the diisobutyryl methanate copper 7 in the supercritical CO₂ fluid 8 before being submitted for the process for forming a conductor in the pressure-resistant reaction container 2, is provided between the material delivery valve 20 and supercritical fluid delivery valve 24, and the pressure-resistant reaction container 2. The light absorption analyzing device 29 can inline-analyze the concentration of the diisobutyryl methanate copper 7 in the supercritical CO₂ fluid 8 before being used for the process for forming a conductor. The use rate of a material in the process for forming a conductor using the conductor forming apparatus 1 can be obtained by obtaining a difference between the concentration of the diisobutyryl methanate copper 7 in the supercritical CO₂ fluid 8 measured by means of this light absorption analyzing device 29 and that of the diisobutyryl methanate copper 7 in the supercritical CO₂ fluid 8 measured by means of the separator 28 described previously.

Further, as shown in FIG. 1, a flow passageway of the supercritical CO₂ fluid 8 from a connection portion between the supercritical fluid supply device 12 and the reaction promoter supply device 14 to the pressure-resistant reaction container 2, is provided inside a second temperature regulator 30. This second temperature regulator 30 is installed in order to adjust a temperature of carbon dioxide serving as a material for the supercritical CO₂ fluid 8 to a temperature at which a supercritical state can be maintained. As described previously, carbon dioxide enters a supercritical state at about 31° C. Therefore, hereinafter, a thermostat 30 capable of stably maintaining a temperature of carbon dioxide at a predetermined temperature is used as the second temperature regulator. Specifically, by means of the thermostat 30, the temperature of carbon dioxide flowing inside the thermostat is maintained at about 40° C. As shown in FIG. 1, inside the thermostat 30, among the flow passageways of the supercritical CO₂ fluid of the conductor forming apparatus, the supercritical fluid delivery valve 24, the material delivery valve 20, the light absorption analyzing device 29, and the pressure-resistant reaction container 2 are housed.

Next, a method for forming a conductor, according to the present embodiment, will be described with reference to FIGS. 2, 3, and 7A to 8. The method for forming a conductor according to the present embodiment is specifically directed to a method for preferentially providing conductors 33 inside a plurality of the fine recesses 5 with high aspect ratio, formed at a top layer part of a processing target 6 using the conductor forming apparatus 1 described previously.

First, as shown in FIG. 2, a silicon wafer 6 serving as the processing target is disposed inside the pressure-resistant reaction container 2. Then, the cooling device 16, supercritical fluid delivery pump 17, mixing unit 23, supercritical fluid delivery valve 24, material delivery pump 19, and material delivery valve 20 are actuated at the supply device 3, with which the conductor forming apparatus 1 is provided. In this manner, the supercritical CO₂ fluid 8 and hydrogen 31 are supplied toward the inside of the pressure resistance reaction container 2 in which the silicon wafer 6 has been housed. In addition, as shown in FIG. 3, the diisobutyryl methanate copper 7 dissolved in acetone 21 is dissolved in the supercritical CO₂ fluid 8 in which hydrogen 31 is mixed, and then, is supplied toward the inside of the pressure resistance reaction container 2. Then, the pressure control valve 26 and the pressure regulator 27 of the discharge device 4, with which the conductor forming apparatus 1 is provided, are actuated, and the upper and lower mantle heaters 11a, 11b, and the thermostat 30 are actuated. In this manner, the internal pressure and temperature of the pressure-resistant reaction container 2 are set and maintained at a value at which the process for forming a conductor can be properly progressed.

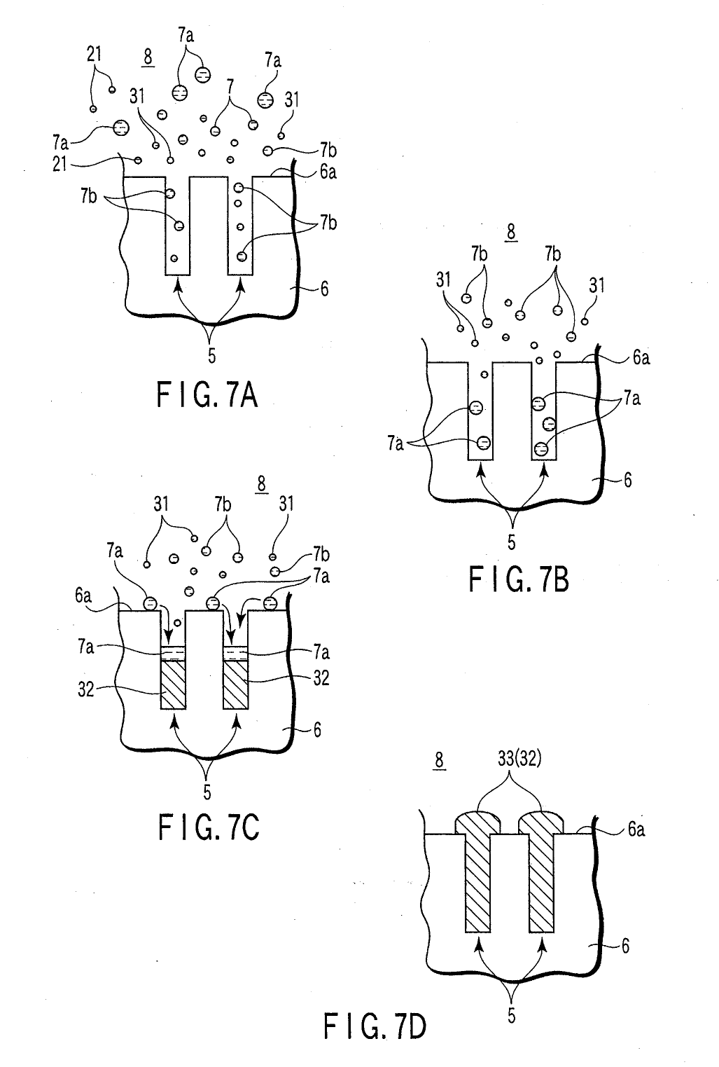

As shown in FIG. 7A, diisobutyryl methanate copper 7a having entered a liquid phase, at least part of which is further converted into molecule-like diisobutyryl methanate copper 7b, is further easily dissolved in the supercritical CO₂ fluid 8. In addition, as described previously, in the present embodiment, hydrogen 31 is added to the supercritical CO₂ fluid 8, and then, diisobutyryl methanate copper 7 is dissolved until an over-saturated state is established in the supercritical CO₂ fluid 8, so that copper 32 easily precipitates from the diisobutyryl methanate copper 7 while the process for forming a conductor is in progress. According to this method, the solubility of the diisobutyryl methanate copper 7 (7a, 7b) in the supercritical CO₂ fluid 8 can be increased by the entrainer effect of the hydrogen 31 without introducing excessive diisobutyryl methanate copper 7 into the pressure-resistant reaction container 2.

The supercritical CO₂ fluid 8 is a very stable substance from the viewpoint of chemical reaction. Therefore, in a state in which the diisobutyryl methanate copper 7b becomes over-saturated relative to the supercritical CO₂ fluid 8, the molecule-like diisobutyryl methanate copper 7b and supercritical CO₂ fluid 8 coexist in an atmosphere in the pressure-resistant reaction container 2 in a double-phase separated state in which their respective phases are separated from each other. In other words, there is almost no danger that the molecule-like diisobutyryl methanate copper 7b and the supercritical CO₂ fluid 8 cause chemical reaction, and are modified. In addition, the supercritical CO₂ fluid 8 has high dispersion equivalent to a gas, so that the molecule-like diisobutyryl methanate copper 7b is dissolved homogenously and substantially uniformly in the supercritical CO₂ fluid 8.

First, as shown in FIG. 7A, when a silicon wafer 6 serving as a foreign substance exists in an atmosphere in which the molecule-like diisobutyryl methanate copper 7b, supercritical CO₂ fluid 8, acetone 21, and hydrogen 31 coexist, the molecule-like diisobutyryl methanate copper 7b is attracted toward the silicon wafer 6 by affinity. Then, the molecule-like diisobutyryl methanate copper 7b is adsorbed or adhered in contact with the surface 6a of the silicon wafer 6. Hence, the molecule-like diisobutyryl methanate copper 7b is dissolved in the supercritical CO₂ fluid 8 having almost no surface tension, whereby a high density state with a very rich fluidity is obtained. Therefore, the molecule-like diisobutyryl methanate copper 7b adsorbed or adhered to the surface 6a of the silicon wafer 6, as shown in FIG. 7A, is introduced in a self-aligned manner and selectively in the recesses 5 made of a structure in which the copper flows smoothly along the surface 6a of the silicon wafer 6, and which is formed at a low position after being engraved from the surface 6a of the silicon wafer 6. In other words, the molecule-like diisobutyryl methanate copper 7b absorbed or adhered to the surface 6a of the silicon wafer 6 is preferentially introduced in the recesses 5.

Next, as shown in FIG. 7B, if the molecule-like diisobutyryl methanate copper 7b enters the recesses 5, a fluctuation occurs in the density of an atmosphere in the pressure-resistant reaction container 2 in the vicinity of the surface 6a of the silicon wafer 6. Finally, a fluctuation occurs in the density of the supercritical CO₂ fluid 8. Specifically, the internal atmosphere of the pressure-resistant reaction container 2 and the density of the supercritical CO₂ fluid 8 becomes high at the upper part in the pressure-resistant reaction container 2 and becomes low at the lower part thereof. Then, a plurality of diisobutyryl methanate coppers 7b molecules dissolved in an over-saturated state in the supercritical CO₂ fluid 8 are attracted to each other, and are aggregated by capillary action. As a result, the liquid diisobutyryl methanate copper 7a precipitates in each of the recesses 5.

Next, as shown in FIG. 7C, the liquid diisobutyryl methanate copper 7a having precipitated in the recesses 5, like a general liquid, sequentially fills the inside of the recesses 5 from a bottom part to an upper part thereof. As described previously, the supercritical CO₂ fluid 8 has high density, so that the molecule-like diisobutyryl methanate copper 7b dissolved in the supercritical CO₂ fluid 8 can enter the inside of the recesses 5 with almost no gap. Therefore, the inside of the recesses 5 are filled with the liquid diisobutyryl methanate copper 7a sequentially and gaplessly from the bottom part to the upper part thereof.

Then, the liquid diisobutyryl methanate copper 7a having precipitated in recesses 5 reacts with the hydrogen 31, and then, is reduced. In this manner, the copper 32 serving as a primary component of the conductor 33 is decomposed from the liquid diisobutyryl methanate copper 7a, and then, precipitates in recesses 5. Therefore, in this process for forming a conductor, the inside of the recesses 5 are filled with the liquid diisobutyryl methanate copper 7a sequentially and gaplessly from the bottom part to the upper part thereof, and at the same time, the copper 32 precipitates sequentially and gaplessly from the bottom part to the upper part inside the recesses 5. In such precipitation reaction of the copper 32, the hydrogen 31 functions as a reducing agent relative to the diisobutyryl methanate copper 7a. Then, the copper 32 having precipitated in the recesses 5 is sequentially deposited from the bottom part to the upper part thereof in the recesses 5 by capillary aggregation. The copper 32 is precipitated in the recesses 5 until the inside of the recesses 5 are filled with the copper 32 with almost no gap. When the hydrogen 31 is consumed in such reductive precipitation reaction of the copper 32 by hydrogen 31, the solubility of the diisobutyryl methanate copper 7b in the supercritical CO₂ fluid 8 is lowered, so that aggregation of the copper 32 is further promoted.

In the present embodiment, while such a process for forming a conductor is in progress, the supercritical CO₂ fluid 8, diisobutyryl methanate copper 7 and the like are supplied by means of the supply device 3 to the inside of the pressure-resistant reaction container 2, and the supercritical CO₂ fluid 8, diisobutyryl methanate copper 7 and the like, which are not submitted for the process for forming a conductor, are continuously discharged outside the pressure-resistant reaction container 2 by means of the discharge device 4. In this manner, the quantity of the supercritical CO₂ fluid 8, diisobutyryl methanate copper 7 and the like in the pressure-resistant reaction container 2 is always adjusted at a proper value in accordance with the progress of the process for forming a conductor, so that the process for forming a conductor can be progressed in a proper state. For example, while the process for forming a conductor is in progress, the quantity of supply to the inside of the pressure-resistant reaction container 2 of the supercritical CO₂ fluid 8, diisobutyryl methanate copper 7 and the like by means of the supply device 3 and the quantity of discharge to the outside of the pressure-resistant reaction container 2 of the supercritical CO₂ fluid 8, diisobutyryl methanate copper 7 and the like, which are not submitted for the process for forming a conductor by means of the discharge device 4, are continuously adjusted. In this manner, the internal pressure of the pressure-resistant reaction container 2, the quantity of the supercritical CO₂ fluid 8, and the quantity and concentration of the diisobutyryl methanate copper 7 can be stabilized at a predetermined value, so that the process for forming a conductor is progressed in a proper state.

In addition, the concentration of the hydrogen 31 in the pressure-resistant reaction container 2 can be stabilized at a predetermined value by adjusting the quantity of supply of the hydrogen 31 into the supercritical CO₂ fluid 8 by means of the reaction promoter supply device 14 and the quantity of discharge of the supercritical CO₂ fluid 8 from the inside of the pressure-resistant reaction container 2 by means of the discharge device 4. In this manner, obviously, the process for forming a conductor can be promoted in a proper state. Further, obviously, the supercritical CO₂ fluid 8 flowing through the flow passageway of the conductor forming apparatus 1 and the internal temperature of the pressure-resistant reaction container 2 are always adjusted to a proper value by means of the upper and lower mantle heaters 11a and 11b and the thermostat 30, whereby the process for forming a conductor can be progressed in a proper state.

Then, as shown in FIG. 7D, after the Cu thin film 33 has been deposited until the thin film (Cu thin film) 33 made of copper 32 overflows on the surface 6a of the silicon wafer 6 from the inside of the recesses 5, the cooling device 16, supercritical fluid delivery pump 17, mixing unit 23, supercritical fluid delivery valve 24, material delivery pump 19, and material delivery valve 20 of the supply device 3 are deactivated to stop the supply of the supercritical CO₂ fluid 8, hydrogen 31, diisobutyryl methanate copper 7, and acetone 21 into the pressure-resistant reaction container 2. Then, it is verified that the superconductor CO2 fluid 8, hydrogen 31, diisobutyryl methanate copper 7, and acetone 21, which have not contributed to the process for forming a conductor, remaining in the pressure-resistant reaction container 2 have been discharged from the inside of the pressure-resistant reaction container 2 by means of the discharge device 4, and then, the pressure control valve 26 and pressure regulator 27 of the discharge device 4 are deactivated. In addition, the upper and lower mantle heaters 11, 11b and the thermostat 30 are deactivated. In this manner, the process for forming a conductor according to the present embodiment is terminated. FIGS. 7A to 7D are enlarged sectional views showing the vicinity of the recesses 5 formed on the silicon wafer 6 in order to clearly explain the process for forming a conductor in the pressure-resistant reaction container 2.

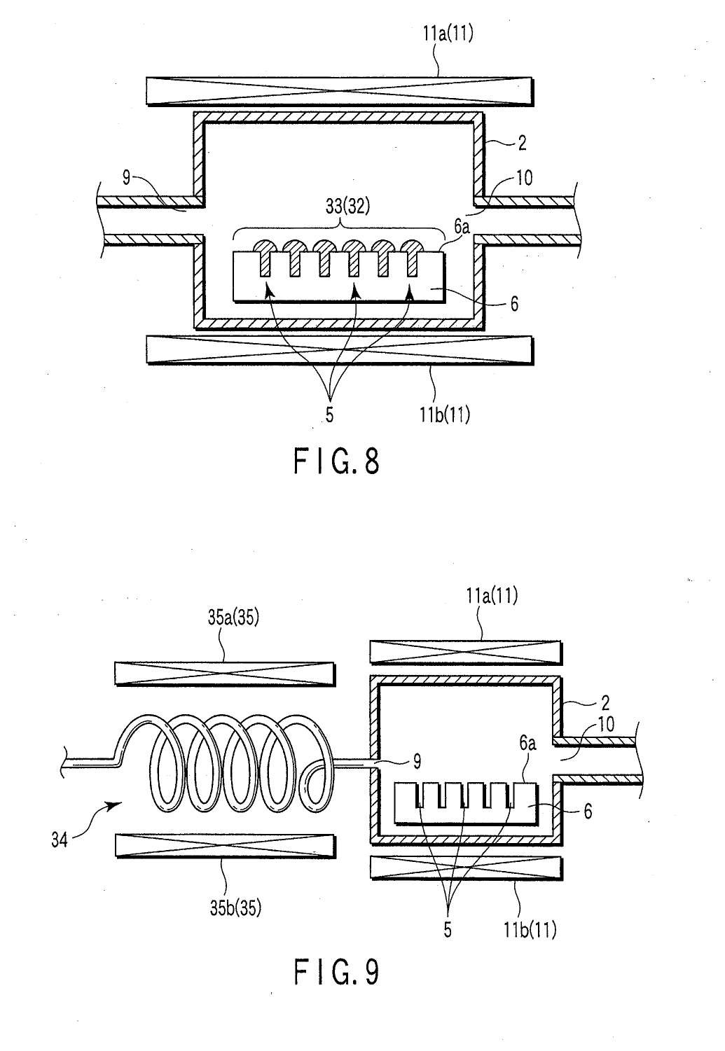

As a result, as shown in FIG. 8, a thin film 33 made of Cu simplex serving as a conductor is preferentially provided inside a plurality of fine recesses 5 with high aspect ratio formed at the top layer part of the silicon wafer 6 and in the vicinity of openings thereof. Then, the inside of the recesses 5 are filled substantially gaplessly with the Cu thin film 33 without voids being formed therein.

As shown in FIG. 1, in the conductor forming apparatus described 1 previously, the light absorption analyzing device 29 is directly connected to the pressure-resistant reaction container 2. However, the configuration is not limited thereto. For example, as shown in FIG. 9, a reaction restriction portion 34 may be connected at the immediately upstream side of the pressure-resistant reaction container 2. The reaction restriction portion 34 introduces into the pressure-resistant reaction container 2 the supercritical CO₂ fluid 8 in which the diisobutyryl methanate copper 7 is dissolved, while restricting reaction of the diisobutyryl methanate copper 7 precipitating from the supercritical CO₂ fluid 8. As such a reaction restriction portion 34, for example, as shown in FIG. 9, a tubular passageway formed in a helical shape may be used. The passageway is capable of, while stirring the supercritical CO₂ fluid 8 in which the diisobutyryl methanate copper 7 has been dissolved, introducing the liquid into the pressure-resistant reaction container 2. In addition, together with this passageway, it is more preferable to provide a third temperature regulator 35 outside the reaction restriction portion 34 for regulating the internal temperature of the reaction restriction portion 34 to a temperature capable of restricting precipitation reaction of the diisobutyryl methanate copper 7 from the supercritical CO₂ fluid 8. In this third temperature regulator 35 as well, as in the first temperature regulator 11 with which the pressure-resistant reaction container 2 described previously is provided, two upper and lower separate-type mantle heaters 35a, 35b may be used so as to uniformly heat the reaction restriction portion 34 from the periphery thereof.

According to the experiment carried out by the inventors, it was found that the supercritical CO₂ fluid 8 in which the diisobutyryl methanate copper 7 has been uniformly dissolved can be introduced into the pressure-resistant reaction container 2, by heating the temperature of the supercritical CO₂ fluid 8 or the like flowing in the reaction restriction portion 34 lower than the internal temperature of the pressure-resistant reaction container 2. For example, it is assumed that the internal temperature of the pressure-resistant reaction container 2 at the time of carrying out the process for forming a conductor is set to about 280° C. In this case, the temperature of the supercritical CO₂ fluid 8 or the like flowing in the reaction restriction portion 34 is set to about 200° C. or less. More preferably, the temperature of the supercritical CO₂ fluid 8 or the like flowing in the reaction restriction portion 34 is set to about 150° C. In this manner, the supercritical CO₂ fluid 8 in which the diisobutyryl methanate copper 7 has been uniformly dissolved can be introduced into the pressure-resistant reaction container 2 while restricting reaction of the diisobutyryl methanate copper 7 precipitating from the supercritical CO₂ fluid 8.

In this way, the reaction restriction portion 34 and the upper and lower mantle heaters 35a, 35b are provided at the immediately upstream side of the pressure-resistant reaction container 2, whereby the quantity and concentration of the diisobutyryl methanate copper 7 introduced into the pressure-resistant reaction container 2 can be controlled with further high precision. As a result, the process for forming a conductor is controlled with further high precision, so that the inside of the fine recesses 5 with high aspect ratio can be efficiently embedded with the Cu thin film 33.

As has been described above, in the first embodiment, the diisobutyryl methanate copper 7 serving as a material for the Cu thin film 33 to be embedded in the recesses 5 is dissolved in the supercritical CO₂ fluid 8 having solubility equivalent to a liquid, high dispersion equivalent to a gas, surface tension which is substantially zero, high density, and nano-level permeability, the fluid being chemically stable. In this manner, the diisobutyryl methanate copper 7 (7a, 7b) can permeate and be charged therein with almost no gap even if an opening width of a plurality of recesses 5 have fineness of about 100 nm or less and high aspect ratio of about 10 to 15. In addition, the diisobutyryl methanate copper (7a, 7b) flows in a self-aligned manner and selectively in the recesses 5 made of a structure that is engraved to be lower than the surface 6a of the silicon wafer 6, irrespective of a material (chemical property) of an inside surface of the recesses 5 serving as an undercoat of the Cu thin film 33. In other words, the metal serving as a main component of a conductor can be preferentially filled in the recesses 5 utilizing an undercoat structure or a physical property, regardless of the undercoat. A method for forming a conductor utilizing such a principle (method for depositing conductor thin films) is also referred to as a shape sensitive deposition technique.

In addition, the inside of the recesses 5 are sequentially charged with almost no gap by the diisobutyryl methanate copper 7 (7a, 7b) from the bottom part to the upper part (opening). Further, from the diisobutyryl methanate copper 7 (7a, 7b) with which the inside of the recesses 5 has been preferentially filled with almost no gap, Cu 32 precipitates sequentially from the diisobutyryl methanate copper 7 (7a, 7b) from the bottom part to the upper part of the recesses 5. In this manner, the inside of the recesses 5 are sequentially filled with a Cu thin film 33 from the bottom part to the upper part thereof. As a result, the recesses 5 are embedded efficiently, selectively, and easily with almost no gap by the Cu thin film 33 irrespective of a material for an undercoat thereof even if the recess is fine and has a high aspect ratio. In this way, a film forming method (deposition method) for sequentially embedding or filling the recesses 5 from the bottom part to the upper part thereof can also be referred to as a bottom-up film forming technique (bottom-up deposition technique).

In addition, in the method for forming a conductor of the present embodiment in which a supercritical fluid and a shape sensitive deposition technique are combined with each other, there is low danger that impurities are mixed in comparison with a CVD technique. In addition, the method for forming a conductor according to the present embodiment, is a much higher density process than a PVD technique or the CVD technique, so that a recesses 5 with high aspect ratio and with complicated shape can be efficiently easily embedded, and then, parts with complicated shape can be produced faster. In other words, the method for forming a conductor according to the present embodiment has high throughput in comparison with the PVD technique or the CVD technique. For example, in the PVD technique or CVD technique, a conductive film is formed fully on the surface of a layer at which a recess is formed, as well as the recess. In contrast, in the method for forming a conductor according to the present embodiment, a conductive film can be selectively formed only inside the recesses 5 or in the vicinity thereof, so that wasteful use of a material hardly occurs in comparison with the PVD technique or CVD technique and a process such as a full face CMP process can be eliminated. In other words, the method for forming a conductor according to the present embodiment is high in productivity in comparison with the PVD technique or CVD technique.

In addition, in an organic metal CVD technique utilizing a liquid material, the liquid material is chemically unstable and small in process margin, whereas in the method for forming a conductor according to the present embodiment, the material is chemically stable and large in process margin. Further, in the method for forming a conductor according to the present embodiment, a ruthenium thin film 21 can be formed at a low temperature in comparison with the PVD technique or CVD technique, so that a process margin of a deposition temperature is wide. In other words, the method for forming a conductor according to the present embodiment can mitigate process temperature dependency. Further, the method for forming a conductor according to the present embodiment is high in recovery rate of expensive and rare materials in comparison with the PVD technique or CVD technique, and is capable of easy reuse thereof. Therefore, the method for forming a conductor according to the present embodiment is efficient in material saving and energy saving in comparison with the PVD technique or CVD technique, and thus, is good in process efficiency and environmentally-friendly. Further, according to the method for forming a conductor of the present embodiment, a process can be eliminated or the use quantity of material can be restricted or reduced in comparison with then PVD technique or CVD technique, so that manufacturing cost can be easily restricted or reduced in comparison with the PVD technique or CVD technique.

Up to now, there have been several proposals for a technique using a supercritical fluid as a CVD carrier gas or a technique utilizing a supercritical fluid as a solvent for a sol-gel film forming technique. However, unlike the present embodiment, with these techniques, a thin film of a conductor cannot be obtained in a supercritical fluid per se. In contrast, in the present embodiment, a thin film 33 of a conductor 32 can be obtained in a supercritical fluid per se, as described previously, and thus, there is no need for redundant processes such as removing a supercritical fluid when the thin film 33 of the conductor 32 is formed. Therefore, in such a point of view as well, it is possible to say that the method for forming a conductor is high in productivity.

In addition, in the batch method for forming a conductor using the closed reaction container described previously, solid diisobutyryl methanate copper has been directly dissolved in a supercritical fluid in the reaction container. The solid diisobutyryl methanate copper is small in steam pressure and is hardly soluble in solvent. Thus, even if a supercritical fluid has a high solvent capability, the diisobutyryl methanate copper is occasionally left insoluble. In other words, in the method for directly dissolving the solid diisobutyryl methanate copper in the supercritical fluid, it has been difficult to precisely control the concentration of the solid diisobutyryl methanate copper in the supercritical fluid. Finally, it has been difficult to improve the use rate of diisobutyryl methanate copper and to promote material saving and cost reduction.

Further, a technique of using a liquid material is also proposed as a technique that overcomes disadvantages caused by using such a solid material. For example, there is proposed a technique of directly dissolving a liquid material including a liquid hexafluoroacetyl acetonate copper (Cu(C₅HF₆O₂) TMVS; Cu(hfac) TMVS) instead of the solid diisobutyryl methanate copper 7. However, the liquid material is generally low in stability, and difficult to handle. In particular, hexafluoroacetyl acetonate copper includes fluorine, and environmental influence such as fluorine contamination is concerned.

In contrast to these techniques, in the present embodiment, the diisobutyryl methanate copper 7 is dissolved in the supercritical CO₂ fluid 8, and then, is introduced into the pressure-resistant reaction container 2 in a substantially liquid state. At this time, prior to dissolving the diisobutyryl methanate copper 7 in the supercritical CO₂ fluid 8, the diisobutyryl methanate copper 7 is dissolved in advance in acetone 21. As described previously, although the solid diisobutyryl methanate copper 7 is small in steam pressure and is hardly dissolved in solvent, the copper can be easily dissolved in the supercritical CO₂ fluid 8 by using an auxiliary solvent such as the acetone 21. In addition, prior to dissolving the diisobutyryl methanate copper 7 in the supercritical CO₂ fluid 8, hydrogen 31 for easily dissolving the diisobutyryl methanate copper 7 in the supercritical CO₂ fluid 8 is dissolved in advance in the supercritical CO₂ fluid 8. Then, after the diisobutyryl methanate copper 7 dissolved in the acetone 21 is dissolved in the hydrogen-dissolved supercritical CO₂ fluid 8, the dissolved copper is introduced into the pressure-resistant reaction container 2.

According to such a method, the solid diisobutyryl methanate copper 7 can be dissolved in the supercritical CO₂ fluid 8. Finally, the diisobutyryl methanate copper 7 that is originally solid can be introduced into the pressure-resistant reaction container 2 in a substantially liquid state.

In addition, in the present embodiment, the supply into the pressure-resistant reaction container 2 of the diisobutyryl methanate copper 7 and the supercritical CO₂ fluid 8 as described previously and the discharge of the diisobutyryl methanate copper 7 and the supercritical CO₂ fluid 8 from the pressure-resistant reaction container 2 are continuously carried out in parallel at least while a conductor forming process for embedding a Cu thin film 33 in recesses 5 is carried out. Further, the quantity of supply into the pressure-resistant reaction container 2 of the diisobutyryl methanate copper 7 and the supercritical CO₂ fluid 8 or the quantity of discharge of the diisobutyryl methanate copper 7 and the supercritical CO₂ fluid 8 from the pressure-resistant reaction container 2 are always adjusted to a proper value in accordance with an embedment situation while the process for forming a conductor is carried out.

According to such a method, while the process for forming a conductor is carried out, the diisobutyryl methanate copper 7, hydrogen 31 and the like can be distributed (made to flow) continuously inside and outside the pressure-resistant reaction container 2. In other words, while a process for forming a conductor is carried out, diisobutyryl methanate copper 7, hydrogen 31 and the like can be continuously supplied quantitatively in the pressure-resistant reaction container 2. Specifically, the internal temperature and pressure of the pressure-resistant reaction container 2, the concentration and quantity of the diisobutyryl methanate copper 7, and the concentration and quantity of hydrogen 31, which serve as film forming parameters of the conductor thin film 33, are always controlled with high precision, so that the process for forming a conductor can be progressed in a proper state. In addition, according to the present embodiment, the diisobutyryl methanate copper 7 serving as a material for the conductor 33 can be continuously supplied into the pressure-resistant reaction container 2. Therefore, in comparison with the conventional batch (closed system) in which the process for forming a conductor terminates at a time point at which the material in the reaction container is consumed, in the process for forming a conductor according to the present embodiment of a flow system (distribution system), there is almost no limitation to the film thickness of the conductor thin film 33.

As a result, according to the present embodiment, while the process for forming a conductor is controlled with high precision, the process is progressed in a proper state, so that the inside of the recesses 5 of the silicon wafer 6 can be speedily and easily embedded by the conductor thin film 33 having a desired film thickness. In addition, the diisobutyryl methanate copper 7 used in the present embodiment is a fluorine-free metal compound. Thus, unlike hexafluoroacetyl acetonate copper or the like, there is almost no concern about environmental influence such as fluorine contamination.

Further, the conductor forming apparatus 1 and the method for forming a conductor according to the present embodiment, in addition to a variety of the features described previously, also have advantageous effects described below. For example, the flow passageway of the supercritical CO₂ fluid 8 of the conductor forming apparatus 1 is closed from the supply device 3 to the discharge device 4, so that there is almost no danger that impurities are mixed in the flow passageway. Thus, there is almost no danger of deteriorating the quality of the silicon wafer 6 having the Cu thin film 33 embedded in the recesses 5 by means of the process for forming a conductor. In addition, the diisobutyryl methanate copper 7 is high in decomposition temperature in comparison with a general CVD material such as hexafluoroacetyl acetonate copper and is low in steam pressure, and thus, is hardly used for a process for forming a metallic film by means of the CVD technique. In contrast, in the present embodiment, the diisobutyryl methanate copper 7 can be used. That is, in the present embodiment, a material such as solid organic metal material that cannot be used in a chemical vapor deposition technique such as the CVD technique can be used, so that the degree of freedom in material is large in comparison with the CVD technique. Further, in the present embodiment, the material density is 10⁴ to 10⁶ times, which is remarkably high in comparison with the conventional method for forming thin films such as the CVD technique. Further, an aspect ratio such as of Micro Electronic Mechanical System (MEMS) and Nano Electronic Mechanical System (NEMS) is high, a complicated structure is provided, and extremely fine machines and parts can be speedily and easily produced. In other words, the present embodiment can be applied to manufacture of machines and parts of a variety of sizes and is an extremely scalable process.

According to another experiment carried out by the inventors, when another supercritical fluid such as Argon (Ar) having no solvent capability is used instead of carbon dioxide, continuous Cu thin film 33 according to the present embodiment was not obtained, but only granular deposition with a plenty of impurities could be obtained. In the study by the inventors regarding this result, the supercritical CO₂ fluid 8 is estimated to actively contribute to a process for forming films such as reduction of impurities in the Cu thin film 33 deposited in the recesses 5. In such a point of view as well, it is found that the process for forming a conductor according to the present embodiment is completely different in principle from a simple technique such as the high-pressure CVD technique.

### Second Embodiment

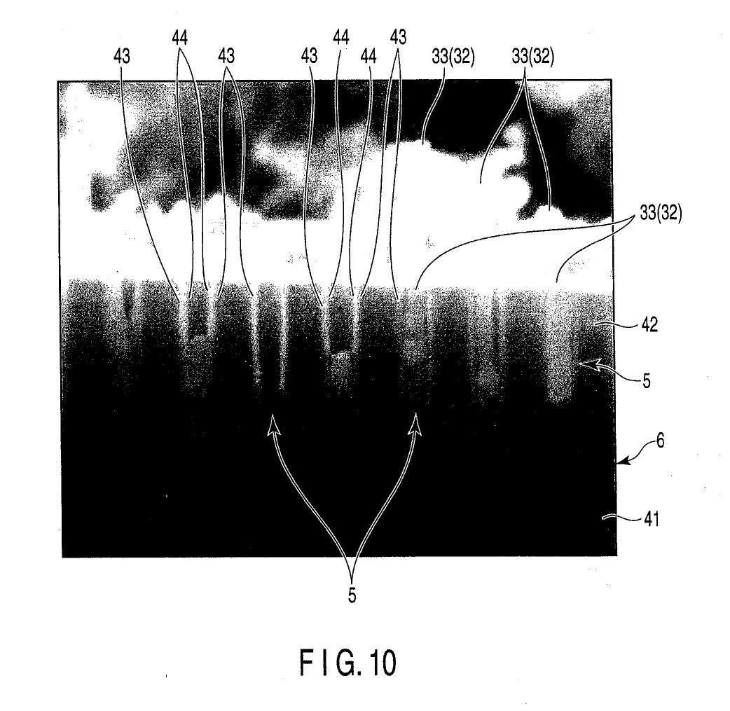

Next, a second embodiment according to the present invention will be described with reference to FIG. 10. The same constituent elements as those in the first embodiment are assigned by the same reference numbers. A detailed description thereof is omitted here. The present embodiment specifically describes a case of providing a Cu thin film 33 made of Cu 32 serving as a conductor in recesses 5 of a silicon wafer 6.

First, as shown in FIG. 10, the silicon wafer 6 used in the present embodiment is based on a configuration in which a silicon dioxide film (SiO₂ film) 42 serving as an insulation film is provided on a silicon layer (Si-layer) 41 serving as a substrate main body. Then, a plurality of fine recesses 5 with high aspect ratio are formed inside the silicon dioxide film 42. Each recess 5 is formed with a width of about 100 nm and a depth of about 500 nm. In other words, the aspect ratio of the each recess 5 is about 5.

Prior to providing the Cu thin film 33 in the recesses 5, on the surface of the silicon dioxide film 42 including inside surfaces of the recesses 5, for example, a titanium nitride (TiN) thin film 43 is fully coated by means of the CVD technique.

In addition, as a metal compound including Cu serving as a material for the Cu thin film 33, a diisobutyryl methanate copper 7 is used as in the first embodiment described previously. Further, the pressure (full pressure) of the atmosphere in the pressure-resistant reaction container 2 is set to about 8.0 MPa. In addition, the temperature of the atmosphere in the pressure-resistant reaction container 2 is set to about 280° C. In addition, the additive pressure of hydrogen 31 is set to about 0.3 MPa. Further, a processing time for film-forming (depositing) the Cu thin film 33 was set to about 15 minutes. Under such a condition, the method for forming a conductor, using the conductor forming apparatus 1 described in the first embodiment is executed. As a result, as shown in FIG. 10, the Cu thin film 33 could be selectively deposited inside and above some of the recesses 5.

As has been described above, according to the second embodiment, using the Cu thin film 33, the inside of the recesses 5 can be preferentially embedded by means of a bottom-up film forming technique (bottom-up deposition technique). In addition, it can be easily understand by one skilled in the art that the Cu thin film 33 made of the shape as shown in FIG. 10 can never be obtained by means of the CVD or PVD technique.

### Third Embodiment

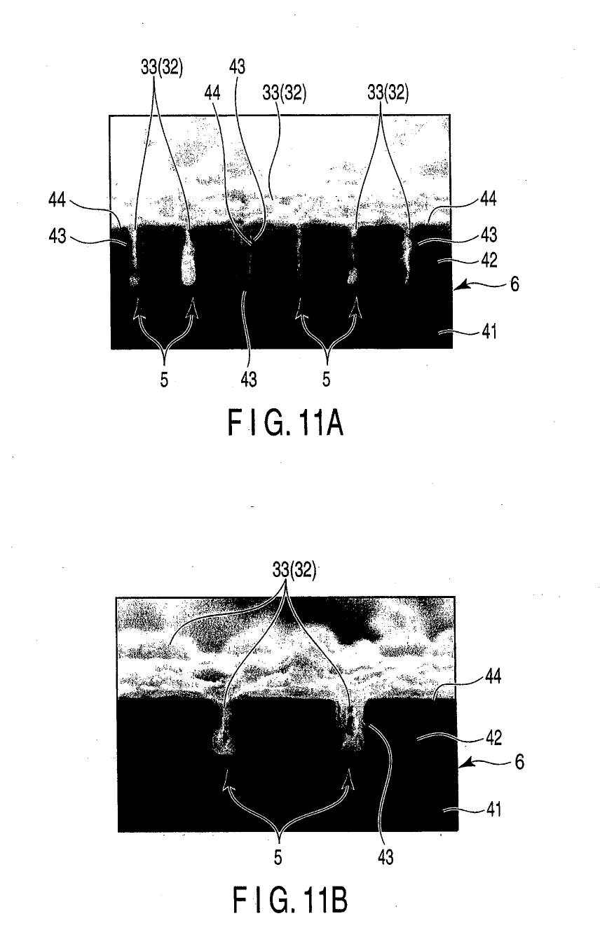

Next, a third embodiment according to the present invention will be described with reference to FIGS. 11A to 17. The same constituent elements as those in the first and second embodiments described previously are designated by the same reference numbers. A detailed description thereof is omitted here. The present embodiment further specifically describes a case in which a thin film 33 made of Cu 32 serving as a conductor is provided in recesses 5 of a silicon wafer 6.

First, in the present embodiment, the silicon wafer 6 made of a configuration similar to the second embodiment described previously is used. In addition, as a metal compound including Cu 32 serving as a material for the Cu thin film 33, diisobutyryl methanate copper 7 is used as in the first embodiment described previously. Then, the concentration of supply of the diisobutyryl methanate copper 7 into the pressure-resistant reaction container 2 is set to about 8.83×10⁻⁵ mol %. The pressure (full pressure) of an atmosphere in the pressure-resistant reaction container 2 is set to about 8.0 MPa. In addition, the temperature of the atmosphere in the pressure-resistant reaction container 2 is set to about 280° C. Further, the additive pressure of hydrogen 31 is set to about 0.3 MPa and the concentration of the hydrogen 31 in the pressure-resistant reaction container 2 is set to about 1.2 mol %. Under such a condition, the method for forming a conductor using the conductor forming apparatus 1 described in the first embodiment was executed. The time for depositing the Cu thin film 33 was set in two ways, i.e., to about 60 minutes and about 90 minutes, and then, the process for forming a conductor was executed.

FIGS. 11A and 11B show a result of the process for forming a conductor in the case where the deposition time of the Cu thin film 33 has been set to about 60 minutes. FIG. 11B is an enlarged cross section showing the vicinity of the recesses 5 of FIG. 11A. As is evident from FIGS. 11A and 11B, it is found that the inside of the recesses 5 is embedded with the Cu thin film 33. In addition, the Cu thin film 33 having overflowed outside the recesses 5 is formed while substantially fully coating a surface 6a of a silicon dioxide film 42 (silicon wafer 6).

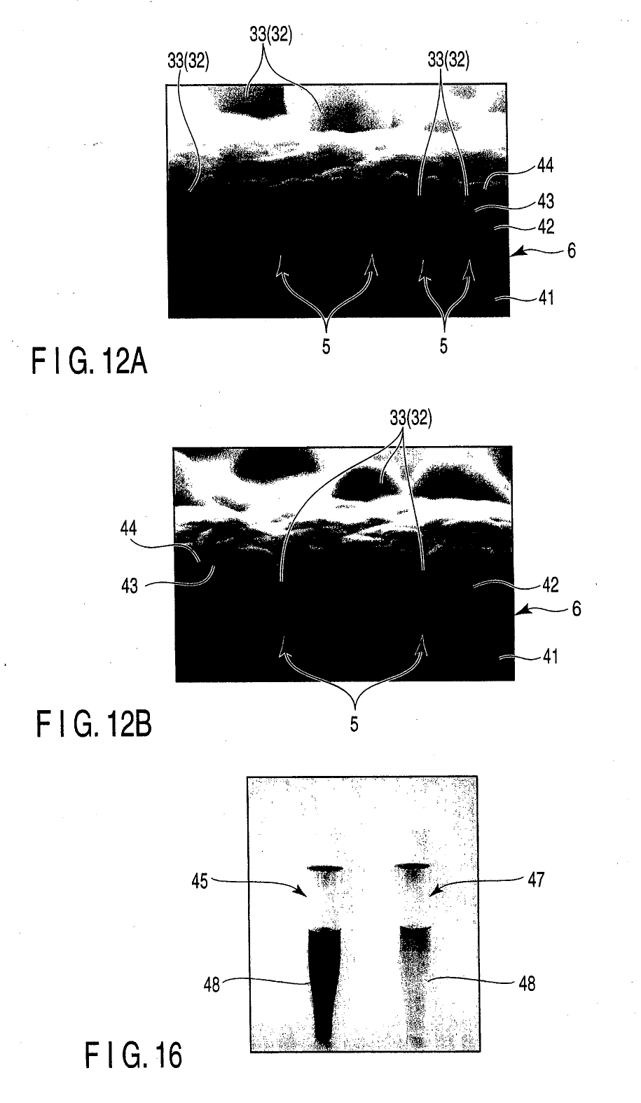

In addition, FIGS. 12A and 12B show a result of the process for forming a conductor in the case where the deposition time of the Cu thin film 33 has been set to about 90 minutes. FIG. 12B is an enlarged cross section showing the vicinity of the recesses 5 of FIG. 12A. As is evident from FIGS. 12A and 12B, it is found that the inside of the recesses 5 are embedded with the Cu thin film 33 as in the case where the deposition time of the Cu thin film 33 described previously has been set to about 60 minutes. In addition, the Cu thin film 33 having overflowed outside the recesses 5 is formed while substantially fully coating the surface 6a of the silicon dioxide film 42 (silicon wafer 6). Further, the film thickness of the Cu thin film 33 on the silicon dioxide film 42 is larger corresponding to additional 30 minutes in deposition time in comparison with the case in which the deposition time of the Cu thin film 33 has been set to about 60 minutes.

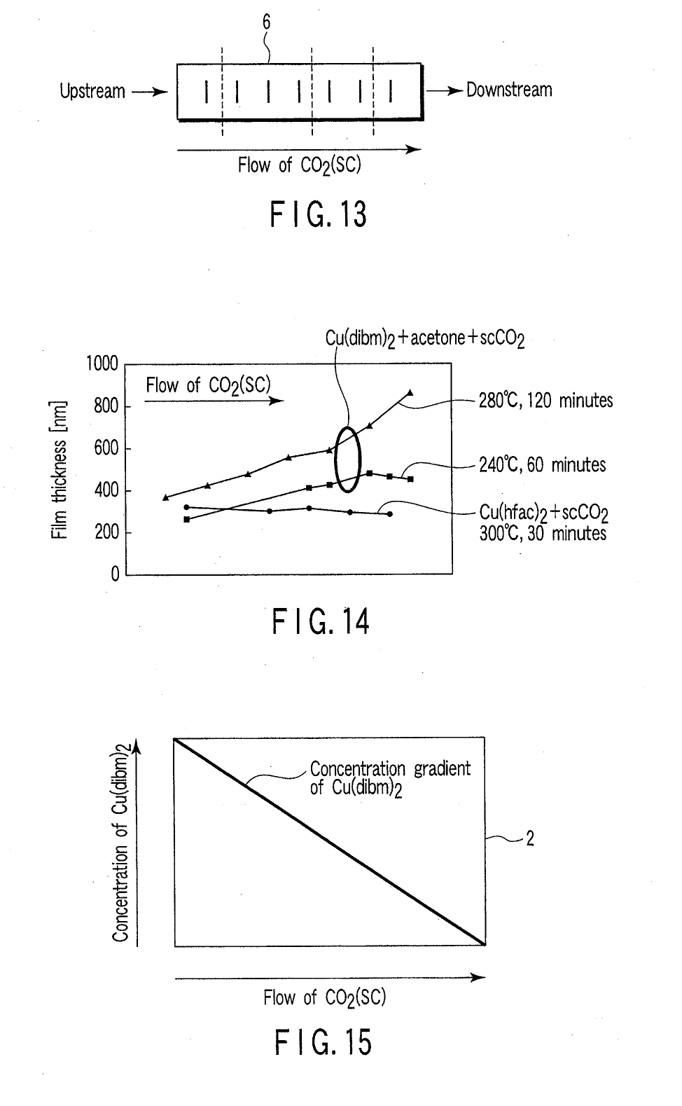

Next, the results of experiment carried out by the inventors with respect to film forming features (deposition features) of the Cu thin film 33 by means of the process for forming a conductor described previously, will be described with reference to FIGS. 13 to 17. In order to more clarify a change in film thickness of the Cu thin film 33 due to a difference in deposition time, the deposition time of the Cu thin film 33 was set in two ways, i.e., to about 60 minutes and about 120 minutes. In addition, the film forming temperature in the case where the deposition time was set to about 60 minutes was set to about 240° C. In contrast, the film forming temperature in the case where the deposition time was set to about 120 minutes was set to 240° C. as in the case described previously.

The inventors, first, as shown in FIG. 13, cut a silicon wafer 6 on which the Cu thin film 33 was deposited by means of the process for forming a conductor, described previously, in a short piece shape of about 10 mm×40 mm. At this time, the inventors cut the silicon wafer 6 so that the longitudinal direction of the silicon wafer 6 formed in the short piece shape is taken along the direction of the flow of the supercritical CO₂ fluid 8 indicated by the solid line arrow in FIG. 13. Then, the inventors investigated the film thickness distribution of the Cu thin film 33 on the silicon wafer 6 cut in the short piece shape. Specifically, the inventors engraved the Cu thin film 33 on the silicon wafer 6 at a plurality of positions indicated by the solid line in FIG. 13 from its upstream side to the downstream side along the direction of the flow of the supercritical CO₂ fluid 8, and then, measured the film thickness by using a step gauge. At this time, the inventors set intervals of the positions indicated by the solid line in FIG. 13 to about 5 mm. In addition, the inventors observed by means of SEM a cross section of the Cu thin film 33 on the silicon wafer 6 at the positions indicated by the dashed line in FIG. 13. The result is shown in FIG. 14.

The graph plotted by the filled triangles in FIG. 14 depicts the film thickness distribution of the Cu thin film 33 on the silicon wafer 6 in the case where the deposition time has been set to about 120 minutes. In addition, the graph plotted by the filled rectangles in FIG. 14 depicts the film thickness distribution of the Cu thin film 33 on the silicon wafer 6 in the case where the deposition time has been set to about 60 minutes. In contrast to these graphs, the graph plotted by the filled circles in FIG. 14 depicts the film thickness distribution in the case where a solid hexafluoroacetyl acetonate copper (Cu (C₅HF₆O₂)₂; Cu (hfac)₂) serving as a material for the Cu thin film is dissolved in the supercritical CO₂ fluid 8, and then, the Cu thin film is formed. The process for forming films using the hexafluoroacetyl acetonate copper was carried out by setting the film forming temperature to about 300° C. and the film forming time to about 30 minutes.

As is evident from three graphs shown in FIG. 14, there appeared a tendency that, only in the case where a hexafluoroacetyl acetonate copper was used as a material for the Cu thin film, the film thickness of the Cu this film was smaller from the upstream side to the downstream side along the direction of the flow of the supercritical CO₂ fluid 8. In contrast, there appeared a tendency that, in the case where a solid diisobutyryl methanate copper 7 dissolved in acetone 21 was used as a material for the Cu thin film 33, the film thickness of the Cu thin film 33 was larger from the upstream side to the downstream side along the direction of the flow of the supercritical CO₂ fluid 8. In addition, it is found that, in the case where the solid diisobutyryl methanate copper 7 dissolved in acetone 21 is used as a material for the Cu thin film 33, the film thickness of the Cu thin film 33 is fully larger on the silicon wafer 6 in the case where the deposition time is set to about 120 minutes in comparison with the case where the deposition time is set to about 60 minutes. In other words, it is found that there is a proportional relationship that, in the case where the solid diisobutyryl methanate copper 7 dissolved in acetone 21 is used as a material for the Cu thin film 33, the film thickness is larger as the deposition time is longer.

According to the research carried out by the inventors, it was found that a main reason why such a phenomenon occurs is that, in the case where the solid diisobutyryl methanate copper 7 dissolved in acetone 21 is used as a material for the Cu thin film 33, while the process for forming a conductor is in progress, there occurs eccentricity in concentration distribution of the diisobutyryl methanate copper 7 in the pressure-resistant reaction container 2. If this mechanism is clearly simplified and illustrated, it can be represented as in FIG. 15.

FIG. 15 graphically depicts the concentration gradient of the diisobutyryl methanate copper 7 in the pressure-resistant reaction container 2 while the process for forming a conductor is in progress, along the direction of the flow of the supercritical CO₂ fluid 8. According to this graph shown in FIG. 15, it is found that the concentration of the diisobutyryl methanate copper 7 in the pressure-resistant reaction container 2 while the process for forming a conductor is in progress is maximal at the supply port 9 side of the pressure-resistant reaction container 2, and becomes smaller toward the discharge port 10 side of the pressure-resistant reaction container 2. This is believed to be because, during the process for forming a conductor, the diisobutyryl methanate copper 7 is consumed sequentially from the upstream side to the downstream side along the flow of the supercritical CO₂ fluid 8 in the pressure-resistant reaction container 2. In other words, the recesses 5 formed on the silicon wafer 6 are believed to be sequentially embedded with the Cu thin film 33 from the upstream side to the downstream side along the flow of the supercritical CO₂ fluid 8.

However, while the process for forming a conductor is in progress, the diisobutyryl methanate copper 7 is made to flow from the upstream side to the downstream side along the flow of the supercritical CO₂ fluid 8. Thus, from the downstream side to the upstream side of the flow of the supercritical CO₂ fluid 8, the Cu thin film 33 becomes harder to be deposited outside the recesses 5. In other words, from the downstream side to the upstream side of the flow of the supercritical CO₂ fluid 8, the Cu thin film 33 becomes harder to be deposited on the surface 6a of the silicon wafer 6. Then, the diisobutyryl methanate copper 7 having flowed from the upstream side to the downstream side along the flow of the supercritical CO₂ fluid 8 easily adheres to the surface at the downstream side of the silicon wafer 6. As a result, the Cu thin film 33 is deposited to be thicker from the upstream side (supply port 9 side) to the downstream side (discharge port 10 side) along the direction of the flow of the supercritical CO₂ fluid 8. Such a mechanism well coincides with tendency of the graphs shown in FIGS. 14 and 15.

Therefore, according to the experiment carried out by the inventors, it is found that in the case where the process for forming a conductor according to the present embodiment is carried out, the concentration or quantity of the diisobutyryl methanate copper 7 supplied into the pressure-resistant reaction container 2 may be set so that the recesses 5 positioned at the most upstream side along the direction of the flow of the supercritical CO₂ fluid 8 in the pressure-resistant reaction container 2 can be filled substantially gaplessly. According to such settings, the inside of all the recesses 5 formed on the silicon wafer 6 including the recesses 5 positioned at the most upstream part along the direction of the flow of the supercritical CO₂ fluid 8 can be filled substantially gaplessly with the Cu thin film 33.

Next, a description will be given with respect to a material use rate of the process for forming a conductor in the experiment carried out by the inventors, described previously. Specifically, as described in the first embodiment, the concentration of the diisobutyryl methanate copper 7 in the supercritical CO₂ fluid 8 before submitted for the process for forming a conductor is measured by means of a light absorption analyzing device 29. In addition, the concentration of the diisobutyryl methanate copper 7 in the supercritical CO₂ fluid 8 after submitted for the process for forming a conductor is measured by means of a separator 28. Then, a concentration difference between these diisobutyryl methanate coppers 7 is obtained. In this manner, a use rate of the diisobutyryl methanate copper 7 in the process for forming a conductor using the conductor forming apparatus 1 is obtained. According to the result of measurement carried out by the inventors, it was found that the use rate of the diisobutyryl methanate copper 7 in the process for forming a conductor using the conductor forming apparatus 1 is about 90% or more. This value is remarkably high in comparison with a general film forming process such as CVD or PVD. In other words, the process for forming a conductor using the conductor forming apparatus 1 is very efficient and can promote material saving.

In addition, FIG. 16 shows, by using photographs, the concentration of the diisobutyryl methanate copper 7 in the supercritical CO₂ fluid 8 before and after submitted for the process for forming a conductor. A test tube 45 at the left side in FIG. 16 is a test tube in which a solution 46 of the diisobutyryl methanate copper 7 before submitted for the process for forming a conductor is filled. In contrast, a test tube 47 at the right side in FIG. 16 is a test tube in which a solution 48 of the diisobutyryl methanate copper 7 after submitted for the process for forming a conductor is filled. In the photographs shown in FIG. 16, a reagent is put in each of the test tubes 45, 47, the reagent exhibiting dark blue as the concentration of the diisobutyryl methanate copper 7 in each of the solutions 46, 48 is high.

As is evident from the photographs shown in FIG. 16, the solution 46 of the diisobutyryl methanate copper 7 put in the test tube 45 is dark in color. Therefore, it is found that the solution 46 of the diisobutyryl methanate copper 7 before submitted for the process for forming a conductor is high in concentration of the diisobutyryl methanate copper 7, and almost no diisobutyryl methanate copper 7 is consumed. As a result, it is found that, the diisobutyryl methanate copper 7 exhibits almost no reaction before submitted for the process for forming a conductor, and is chemically stable. In contrast, the solution 48 of the diisobutyryl methanate copper 7 put in the test tube 47 is light in color, and is almost transparent with no color. Therefore, it is found that the solution 48 of the diisobutyryl methanate copper 7 after submitted for the process for forming a conductor is low in concentration of the diisobutyryl methanate copper 7, and almost all diisobutyryl methanate copper 7 is consumed. In other words, it is found that, according to the photographs shown in FIG. 16, the use rate of the diisobutyryl methanate copper 7 in the process for forming a conductor using the conductor forming apparatus 1 is very high and almost all the diisobutyryl methanate copper 7 is consumed in the process for forming a conductor in the pressure-resistant reaction container 2.

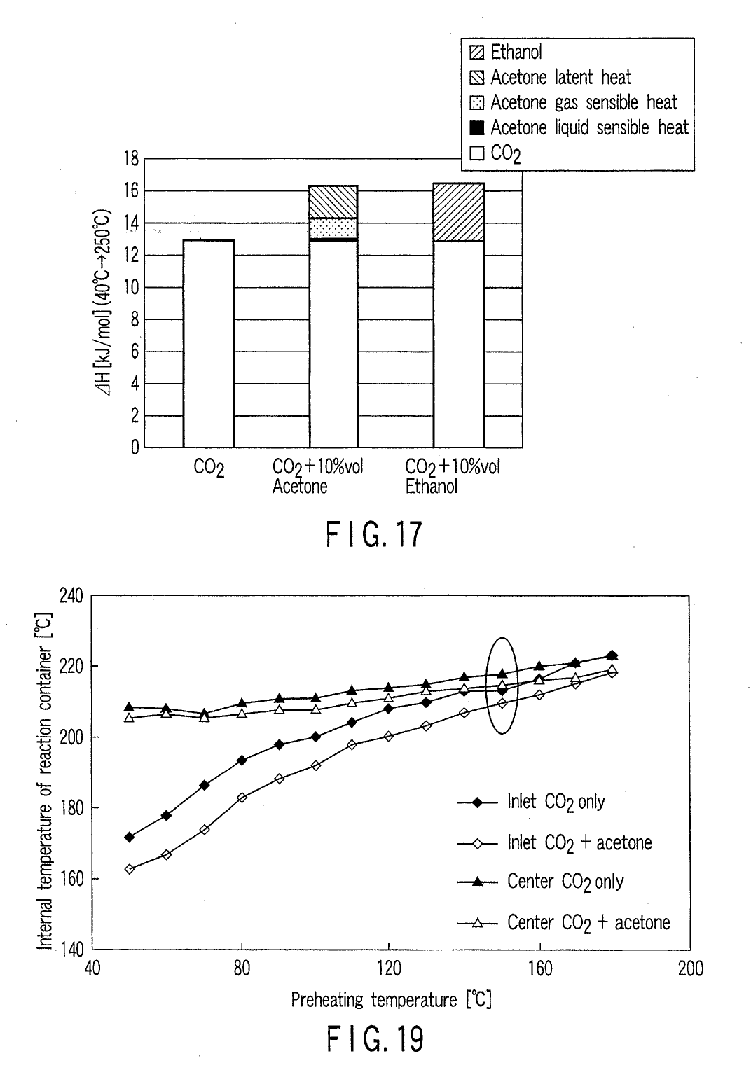

Further, the inventors calculated a change of enthalpy in the case where a variety of additives have been added in the supercritical CO₂ fluid 8. The calculation result is shown in FIG. 17. The graph shown in FIG. 17 shows the results of measurement relevant to a change of enthalpy when the supercritical CO₂ fluid 8 with no additive, the supercritical CO₂ fluid 8 added with acetone 21, and the supercritical CO₂ fluid 8 added with ethanol are poured into the pressure-resistant reaction container 2, respectively. According to the graph shown in FIG. 17, it is found that, at the time of executing the process for forming a conductor, in the case where acetone 21 is added into the supercritical CO₂ fluid 8, a heat quantity of about 1.27 times is required in comparison with the supercritical CO₂ fluid 8 with no additive.

According to research carried out by the inventors, it was believed that such a rapid change of enthalpy may relate to distribution of film thickness of the Cu thin film 33 shown in FIG. 14. Specifically, in the case where the supercritical CO₂ fluid 8 added with acetone 21 is used, when the supercritical CO₂ fluid 8 is poured into the pressure-resistant reaction container 2, the temperature of the vicinity of the supply port 9 is rapidly lowered. Therefore, the Cu thin film deposition reaction in the vicinity of the supply port 9 in the pressure-resistant reaction container 2 becomes slow. As a result, the film thickness of the Cu thin film 33 is small in the vicinity of the supply port 9 and is large in the vicinity of the discharge port 10. In other words, as described previously, the film thickness of the Cu thin film 33 is larger from the upstream side toward the downstream side of the flow of the supercritical CO₂ fluid 8.

As has been described above, according to the third embodiment, advantageous effect similar to that of the second embodiment described previously can be attained. In addition, according to the present embodiment, the inside of the recesses 5 formed on the silicon wafer 6 can be selectively embedded with the Cu thin film 33, and the Cu thin film 33 can be fully deposited on the surface 6a of the silicon wafer 6 in the same manner as in a general CVD technique or PVD technique.

### Fourth Embodiment

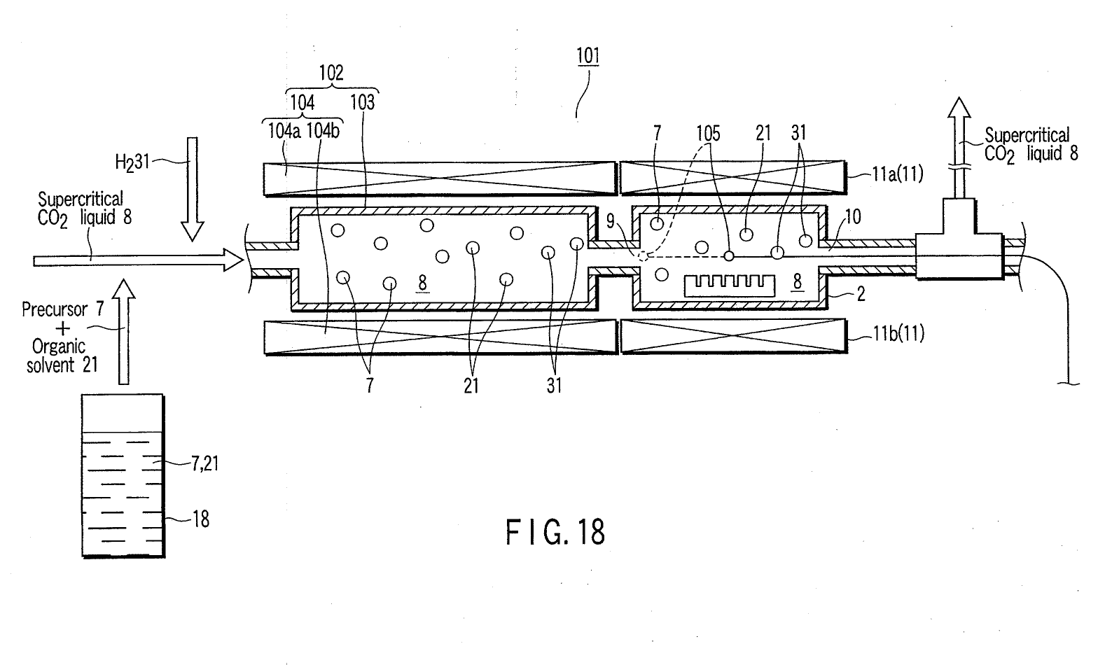

Next, a fourth embodiment according to the present embodiment will be described with reference to FIGS. 18 to 23C. The same constituent elements as those in the first to third embodiments described previously are designated by the same reference numbers. A detailed description thereof is omitted here. In the present embodiment, unlike the first to third embodiments, prior to introducing the supercritical CO₂ fluid or the like into the reaction container, preheating is carried out up to a predetermined temperature. In this manner, an attempt is made to obtain a better embedment state or film forming result. Hereinafter, a specific description will be given.

First, FIG. 18 schematically shows essential portions of a conductor forming apparatus 101 according to the present embodiment. In the conductor forming apparatus 101 according to the present embodiment, unlike the conductor forming apparatus 1 according to the first embodiment, a preheat apparatus (preheat system, preheat unit) 102 is connected at the immediately upstream side of the pressure-resistant reaction container 2. The apparatus 102 is for preheating up to a predetermined temperature a substance to be introduced into the pressure-resistant reaction container 2, prior to introducing the substance into the pressure-resistant reaction container 2. In FIG. 18, although not shown, obviously, the preheat system 102 is connected to the more downstream side than the supply device 3. This preheat system 102 consists of a preheat chamber 103, a fourth temperature regulator 104 and the like.

To the inside of the preheat chamber 103, supercritical CO₂ fluid 8, reaction promoter (H₂) 31, precursor (diisobutyryl methanate) 7, organic solvent (acetone) 21 and the like are supplied from the supply device 3. In the following description, these substances supplied from the supply device 3 to the inside of the preheat chamber 103 are simply referred to as the supercritical CO₂ fluid 8 unless otherwise specified. The supercritical CO₂ fluid 8 is introduced into the pressure-resistant reaction container 2 after preheated in the preheat chamber 103.

The fourth temperature regulator 104, specifically, as in the first and third temperature regulators 11 and 35 described previously, is a mantle heater unit 104 composed of two heaters, i.e., an upper mantle heater 104a and a lower mantle heater 104b capable of heating the inside of the preheat chamber 103 from an upper part and lower part thereof, respectively independently. The internal temperature of the preheat chamber 103 is heated by means of the mantle heater unit 104, and then, is risen up to a predetermined temperature. The upper limit of the internal temperature of the preheat chamber 103 is set to a value lower than that of the pressure-resistant reaction container 2 when the process for forming a conductor is carried out. For example, the temperature of the supercritical CO₂ fluid 8 in the preheat chamber 103 is preheated by means of the mantle heater unit 104, and then, is risen up to a predetermined temperature of about 180° C. or less.

Next, two types of experiments carried out by the inventors using the conductor forming apparatus 101 will be described with reference to FIGS. 18 to 23C. One is an experiment for measuring the internal temperature of the pressure-resistant reaction container 2 and the other one is an experiment for forming a Cu thin film.

First, the experiment for measuring the internal temperature of the pressure-resistant reaction container 2 will be described with reference to FIGS. 18 and 19. When carrying out this experiment, conditions were set as described below. First, as supercritical CO₂ fluids 8 to be supplied into the preheat chamber 103, there are used a supercritical CO₂ added with no acetone 21; and a supercritical CO₂ fluid in which a flow rate of acetone 21 mixed therein was set to about 10 vol %. Secondly, the external temperature of the pressure resistance reaction container 2 is set to about 250° C. by using a thermostat 30, although not shown. Thirdly, a capacity ratio between the pressure resistance reaction container 2 and the preheat chamber 103 is set to about 1:3. Under such settings, by heating the inside of the preheat chamber 103 using the upper and lower mantle heaters 104a, 104b, the internal temperature (preheat temperature) of the preheat chamber 103 was changed from about 50° C. to about 180° C. Then, as shown in FIG. 18, the internal temperature of the pressure-resistant reaction container 2 supplied with the supercritical CO₂ fluid 8 heated in the preheat chamber 103 was measured by means of a thermocouple 105 at two sites, i.e., in the vicinity of the inlet (supply port) 9 and in the vicinity of the center part. The result is graphically shown in FIG. 19.

According to the graph shown in FIG. 19, it is found that, at a time point at which the preheat temperature has reached about 150° C., there is almost no difference in internal temperature at the two sites, i.e., the vicinity of the inlet 9 of the pressure-resistant reaction container 2 and the vicinity of the center part. In addition, it is found that such a phenomenon does not depend on the presence or absence of acetone 21 in the supercritical CO₂ fluid 8.

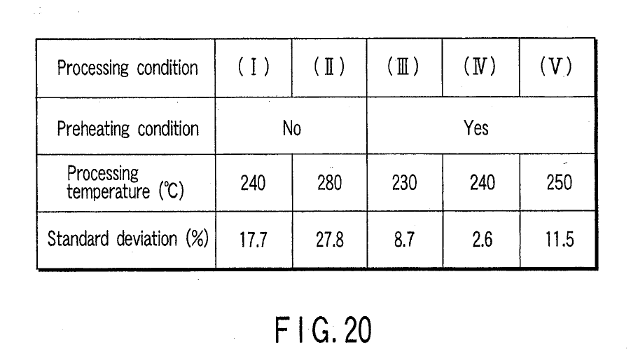

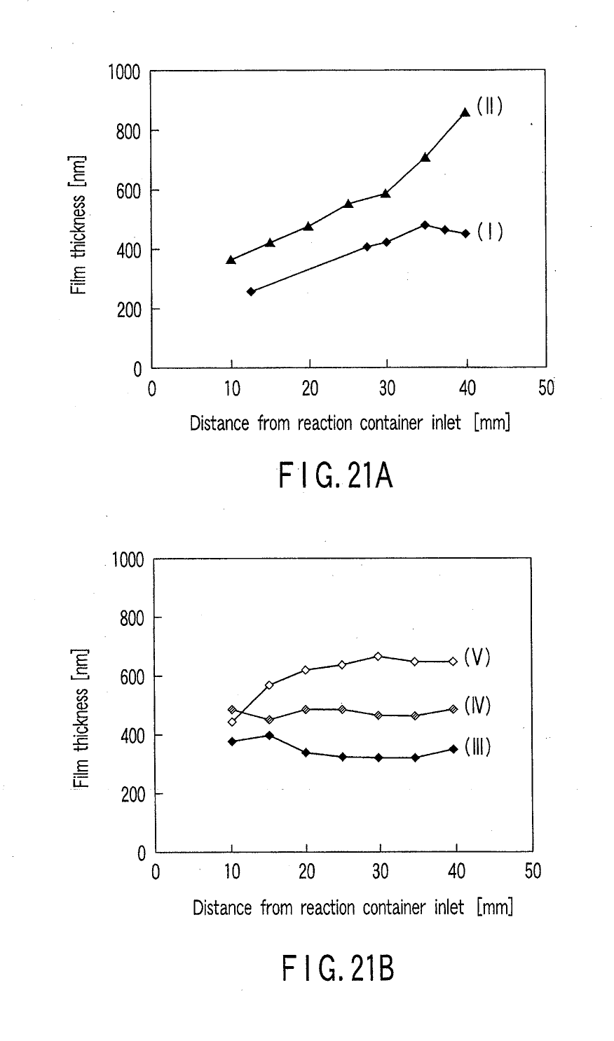

Next, an experiment of forming a Cu thin film will be described with reference to FIGS. 20 to 23C. In this experiment of forming the Cu thin film, specifically, as shown in FIG. 20, five types of processing conditions, I to V, were set, and then, a process for forming a conductor, similar to that of the first embodiment, was carried out using the conductor forming apparatus 101. The result is shown at the bottom stage of the table in FIG. 20 and is graphically shown in FIGS. 21A and 21B. In the table shown in FIG. 20, a processing temperature denotes an internal temperature of the pressure-resistant reaction container 2 when the process for forming a conductor is carried out and a standard deviation denotes a film thickness deviation of the Cu thin film formed. In addition, the two graphs shown in FIG. 21A each show a film forming result in the case where preheating is not carried out, and the three graphs shown in FIG. 21B each show a film forming result in the case where preheating is carried out.

According to the table shown in FIG. 20, it is found that, in the case where preheating is not carried out, as the processing temperature is high, the film thickness deviation of the Cu thin film formed on the silicon wafer is large. In addition, according to the graph shown in FIG. 21A, it is found that, in the case where preheating is not carried out, the film thickness of the Cu thin film formed on the silicon wafer is larger from the vicinity of the inlet 9 of the pressure-resistant reaction container 2 toward the center part and the vicinity of an outlet (discharge port) 10. In other words, it is found that there is a tendency that the Cu thin film is deposited more thickly from the upstream side toward the downstream side along the direction of the flow of the supercritical CO₂ fluid 8. Then, it is found that the higher the processing temperature is, the more remarkable the tendency becomes. Further, it is found that the higher the processing temperature is, the thicker the Cu thin film becomes.

In contrast, according to the table shown in FIG. 20, it is found that, in the case where preheating is carried out, the film thickness deviation of the Cu thin film formed on the silicon wafer is not always proportional to the degree of the processing temperature. In addition, it is found that, in the case where preheating is carried out, the film thickness deviation of the Cu thin film can be restricted to less than about 1/10 at maximum in comparison with the case in which preheating is not carried out. For example, it is found that, in the case where the processing temperature is set to about 240° C., the film thickness deviation of the Cu thin film can be restricted to about 1/7. In addition, according to the graph shown in FIG. 21B, it is found that, in the case where preheating is carried out, the film thickness of the Cu thin film formed on the silicon wafer is substantially the same in the vicinity of the inlet 9 of the pressure-resistant reaction container 2 and in the center part and the vicinity of the outlet 10, and is significantly uniformed in comparison with the case in which preheating is not carried out. In other words, it is found that there is a tendency that the Cu thin film is deposited with substantially uniform film thickness irrespective of the position of the flow of the supercritical CO₂ fluid 8. However, in the case where preheating is carried out, as in the case where preheating is not carried out, it is found that the higher the processing temperature is, the thicker the Cu thin film becomes.

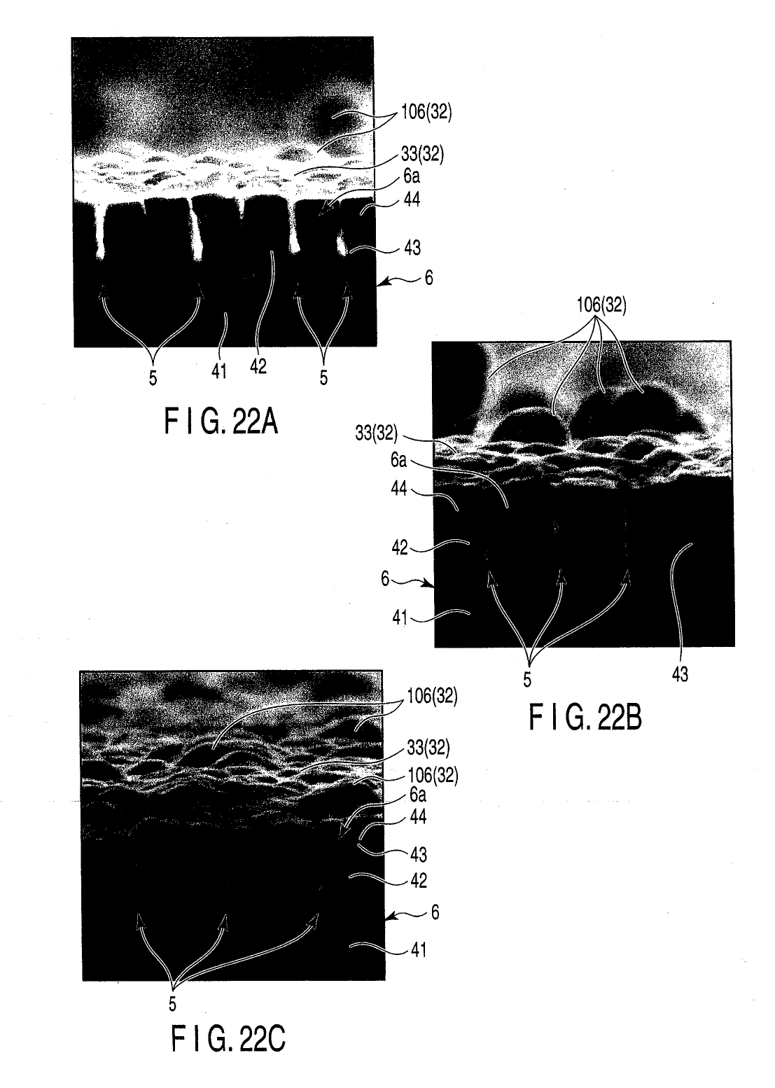

Next, FIGS. 22A to 22C each show an SEM photograph of a result of forming the Cu thin film 33 on the silicon wafer 6 under processing condition II among processing conditions I to V in the table shown in FIG. 20. More specifically, FIG. 22A shows a sectional SEM photograph of the silicon wafer 6 in the vicinity of the inlet 9 of the pressure-resistant reaction container 2 and the Cu thin film 33 formed thereon. In addition, FIG. 22B shows a sectional SEM photograph of the silicon wafer 6 in the vicinity of the center part of the pressure-resistant reaction container 2 and the Cu thin film 33 formed thereon. Further, FIG. 22C shows a sectional SEM photograph of the silicon wafer 6 in the vicinity of the outlet 10 of the pressure-resistant reaction container 2 and the Cu thin film 33 formed thereon. The silicon wafer 6 used in this experiment is made of the same structure as the silicon wafer 6 described in the second embodiment.

As is evident from the SEM photographs shown in FIGS. 22A to 22C, the Cu thin film 33 is fully formed on the surface 6a of the silicon wafer 6 in each one of the vicinities of the inlet 9, the center part, and the outlet 10 of the pressure-resistant reaction container 2. In addition, it is found that the inside of the recesses 5 formed on the silicon wafer 6 is filled with the Cu thin film 33 and the embeddability is appropriate. However, irrespective of the position on the surface 6a of the silicon wafer 6, a number of granular Cu depositions 106 made of Cu 32 that has abnormally grown are observed on the Cu thin film 33. Further, although the Cu thin film 33 is fully formed as a continuous film on the surface 6a of the silicon wafer 6, a number of irregularities are observed on the surface thereof. In this manner, in the case where the Cu thin film is formed under processing condition II without preheating, the film thickness is not always entirely well formed.

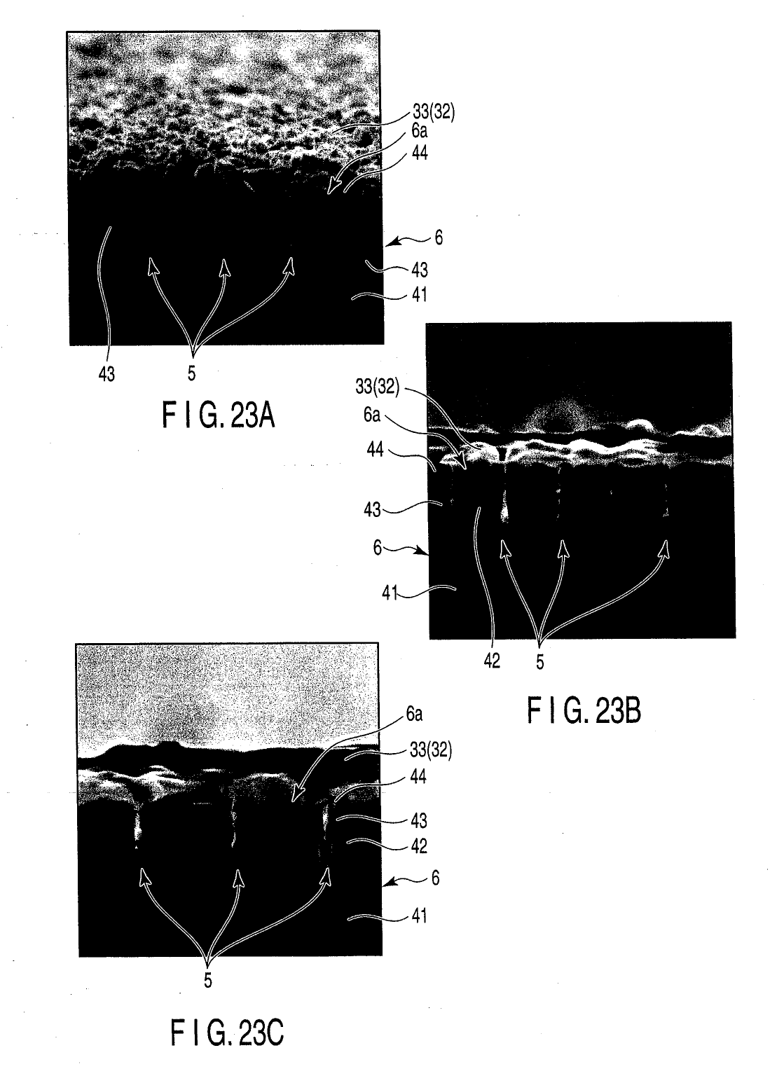

Next, FIGS. 23A to 23C each show an SEM photograph of a result of forming the Cu thin film 33 on the silicon wafer 6 under processing condition V among processing conditions I to V in the table shown in FIG. 20. More specifically, FIG. 23A shows a sectional SEM photograph of the silicon wafer 6 in the vicinity of the inlet 9 of the pressure-resistant reaction container 2 and the Cu thin film 33 formed thereon. In addition, FIG. 23B shows a sectional SEM photograph of the silicon wafer 6 in the vicinity of the center part of the pressure-resistant reaction container 2 and the Cu thin film 33 formed thereon. Further, FIG. 23C shows a sectional SEM photograph of the silicon wafer 6 in the vicinity of the outlet 10 of the pressure-resistant reaction container 2 and the Cu thin film 33 formed thereon.

As is evident from the SEM photographs shown in FIGS. 23A to 23C, in the case where the Cu thin film 33 is formed under processing condition V in the table shown in FIG. 20 as well, as in the case where the Cu thin film 33 is formed under processing condition II, the Cu thin film 33 is fully formed on the surface 6a of the silicon wafer 6 in each one of the vicinities of the inlet 9, the center part, and the outlet 10 of the pressure-resistant reaction container 2. In addition, as in the case where the Cu thin film 33 is formed under processing condition II, it is found that the inside of the recesses 5 formed on the silicon wafer 6 is filled with the Cu thin film 33 and the embeddability is also good. However, in the case where the Cu thin film 33 is formed under processing condition V, unlike the case where the Cu thin film 33 is formed under processing condition II, the granular Cu deposition 106 made of Cu 32 that has abnormally grown is hardly observed on the surface of the Cu thin film 33 irrespective of the position on the surface 6a of the silicon wafer 6. In addition, irregularities are hardly observed on the surface of the Cu thin film 33. In this way, in the case where the Cu thin film 33 is formed under processing condition V with preheating, it is found that the Cu thin film 33 with a more improved film quality can be formed in comparison with the case in which the Cu thin film 33 is formed under processing condition II without preheating.

As has been described above, according to the fourth embodiment, advantageous effect similar to those of the first to third embodiments described previously can be attained. In addition, by applying preheating in advance prior to introducing the supercritical CO₂ fluid 8 added with acetone 21 into the pressure-resistant reaction container 2, preliminary reduction of copper is executed to accelerate a reaction rate. Therefore, it is possible to improve a tendency that the film thickness of the Cu thin film 33 is deposited more thickly from the upstream side to the downstream side along the direction of the flow of the supercritical CO₂ fluid 8. As a result, the Cu thin film 33 made of homogenous and substantially uniform film thickness can be substantially fully formed on the surface 6a of the silicon wafer 6 irrespective of the position in the pressure-resistant reaction container 2.

When a preheat system 102 is used as a reaction promoting system, advantages such as promotion of thermal reaction, generation of an intermediate reaction species, and the like can be obtained even by merely executing preheating. These advantages become more significant by preliminarily arranging inside the preheating chamber 103 a metal which becomes a catalytic substance such as platinum (Pt), paradium (Pd), nickel (Ni) or copper (Cu), prior to executing the preheating. In this case, for example, each of the metals may be formed in a plate shape or wire shape and arranged inside the preheating chamber 103, deposited on an inner wall surface of the preheating chamber 103, or placed on or suspended from a support member composed of a porous body provided inside the preheating chamber 103, though they are not shown.

In addition, a preheat system 102 according to the present embodiment may be used together with the reaction restriction portion 34 described in the first embodiment. In this case, the preheat system 102 may be provided between the reaction restriction portion 34 and the pressure-resistant reaction container 2. With such a configuration, function of the reaction restriction portion 34 and that of the preheat system 102 can be exerted without any mutual contradiction.

The preheating described previously does not always need to be carried out up to the vicinity of a temperature at which the process for forming a conductor is carried out. At a critical point at which acetone 21 is established in a supercritical state, a temperature is set to about 235° C. and a pressure is set to about 4.76 MPa. Therefore, in the case where the supercritical CO₂ fluid 8 added with acetone 21 is used, it is sufficient as long as the supercritical CO₂ fluid 8 added with acetone 21 is heated up to about 235° C. and the pressure is caused to reach about 4.76 MPa prior to inflow of the fluid into the pressure-resistant reaction container 2.

### Fifth Embodiment

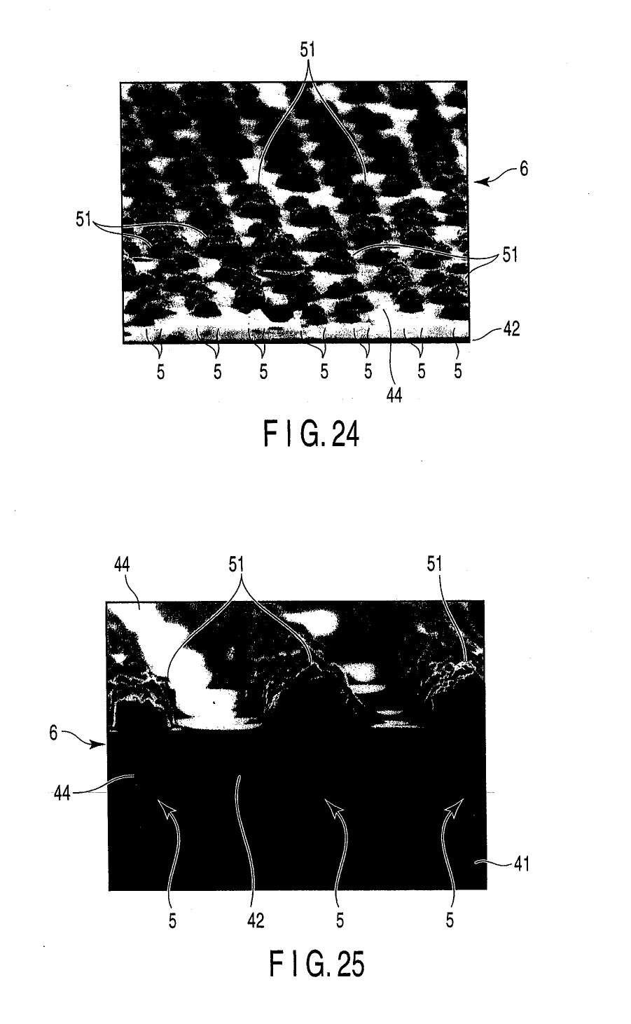

Now, a fifth embodiment according to the present invention will be described with reference to FIGS. 24 and 25. The same constituent elements as those in the first to fourth embodiments described previously are designated by the same reference numbers. A detailed description thereof is omitted here. In the present embodiment, unlike the first to fourth embodiments, a description will be given with respect to a case of embedding the inside of the recesses 5 of the silicon wafer 6 by using a thin film made of ruthenium (Ru) instead of the Cu thin film 33.

First, a silicon wafer 6 made of substantially the same configuration as the silicon wafers 6 used in the second and third embodiments described previously is used here. However, unlike the silicon wafers 6 used in the second and third embodiments, a TIN thin film 43 is not provided on the inside surface of the recesses 5 or the surface of the silicon dioxide film 42. An Au thin film 44 is only fully coated on the inside surface of the recesses 5 and the surface of the silicon dioxide film 42. In addition, the recesses 5 are formed in the silicon dioxide film 42. In addition, the dimensions of the recesses 5 are formed so that the width of a bottom part is about 130 nm, the width of an opening is about 200 nm, and the depth is about 2 μm. In other words, the aspect ratio of the each recess 5 is about 10 to 15. The flow-type process for forming a conductor is executed for the silicon wafer 6 made of such a configuration.

Here, as a material for the Ru thin film, there is used cyclopentadienyl ruthenium (Ru(C₅H₅)₂; RuCp₂) serving as an organic metal complex similar to the diisobutyryl methanate copper 7. Then, the concentration of cyclopentadienyl ruthenium 18 in the supercritical CO₂ fluid 8 is set to about 25 mg/cc and the additive pressure of hydrogen 19 is set to about 1.0 MPa. In addition, the pressure (full pressure) of the atmosphere in the pressure-resistant reaction container 2 is set to about 12 MPa. Further, the internal temperature of the pressure-resistant reaction container 2 at the time of executing the process for forming a conductor is set to about 250° C. In addition, the processing time for the process for forming a conductor is set to about 15 minutes. Under such conditions, the inventors carried out the process for forming a conductor, described previously. The results are shown in FIGS. 24 and 25 using SEM photographs. FIG. 25 is an enlarged cross section showing the vicinity of the recesses 5 of FIG. 24.

As shown in FIGS. 24 and 25, it was verified that a Ru thin film (ruthenium island) 51 formed in a mushroom shape could be formed selectively along the recesses 5 on the Au thin film 44 configuring the surface 6a of the silicon wafer 6. In addition, as shown in FIG. 24, it was verified that the inside of the recesses 5 could be filled almost gaplessly from the bottom part to the upper part thereof, as in the third embodiment described previously.

As has been described above, according to the fifth embodiment, even if Ru is used instead of Cu, advantageous effect similar to those of the first to fourth embodiments can be attained.

### Sixth Embodiment

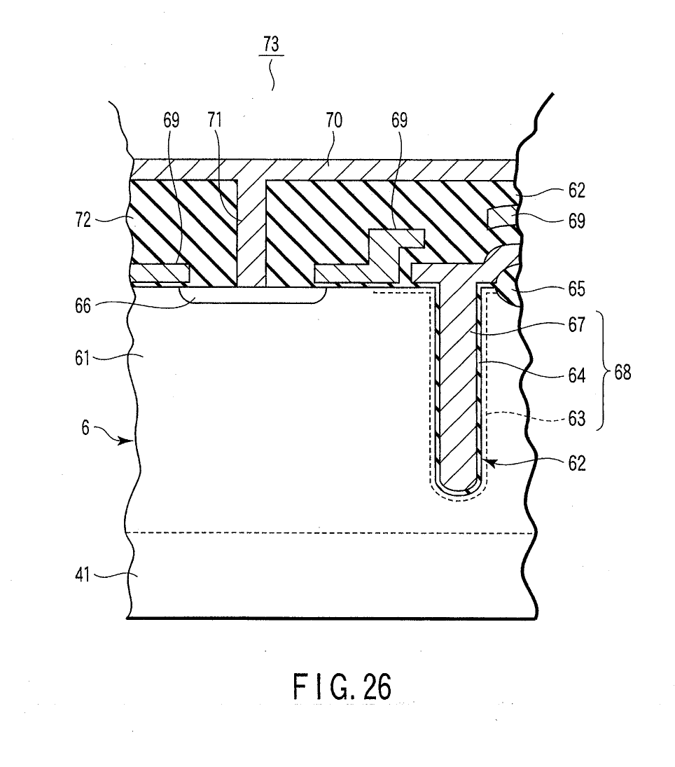

Next, a sixth embodiment according to the present invention will be described with reference to FIG. 26. The same constituent elements as those in the first to fifth embodiments described previously are assigned by the same reference numbers. A detailed description thereof is omitted here. The present embodiment describes a technique of manufacturing semiconductor devices by using the method for forming a conductor, described in the first embodiment. Specifically, an embedding electrode of a trench capacitor is formed using the method for forming a conductor, described previously.

As shown in FIG. 26, a substrate main body of the silicon wafer 6 used in the present embodiment is composed of a P-type silicon layer (Si layer) 22. In addition, a surface layer portion of the P-type silicon layer 22 is a P-well 61. Further, a fine recess (trench) 62 with high aspect ratio is formed inside the P-well 61 serving as a surface layer portion of the silicon wafer 6. N-type impurities are introduced into the surface layer portion inside the P-well 61 by means of a technique such as ion implantation, and a cathode 63 of a trench capacitor 68 is obtained. In addition, inside of trench 62, a silicon oxide film (SiO₂ film) 64 serving as a capacitor insulation film is provided over the surface of the cathode 63. Further, an element isolation area 65 and an n+impurity diffusion area 66 serving as a source area or a drain area of a transistor (not shown), are formed at the surface layer portion of the silicon wafer 6.

After the silicon wafer 6 made of such a configuration is housed in the pressure-resistant reaction container 2, the method for forming a conductor described in the first embodiment is executed. At this time, in the case where the conductor provided in the trench 62 is formed of Cu, any of the processing conditions in the second to fourth embodiments described previously may be employed. In addition, in the case where the conductor provided in the trench 62 is formed of Ru, the processing condition of the fifth embodiment described previously may be employed. Here, it is assumed that the inside of the trench 62 is embedded with a Ru thin film 67. In this manner, the Ru thin film 67 serving as an embedding electrode of the trench capacitor 68 can be formed selectively and with almost no gap inside the fine trench 62 with high aspect ratio and at the periphery of an opening thereof. After the process for forming the Ru thin film 67 is terminated, the silicon wafer 6 is taken out from the inside of the pressure-resistant reaction container 2, and then, the Ru thin film 67 is molded in the shape of a desired embedding electrode by means of an etching process. In this manner, a plate electrode 67 serving as an embedding electrode formed in a desired shape by using the Ru thin film is provided at the surface layer portion of the silicon wafer 6. As a result, the trench capacitor 68 composed of the cathode 63, the capacitance insulation film 64, and the plate electrode 67 is provided at the surface layer portion of the silicon wafer 6.

Thereafter, on the surface 6a of the silicon wafer 6 on which the trench capacitor 68 has been provided, there may be provided: a word 69 or a bit line 70; a contact plug 71 for obtaining conductivity between the bit line 70 and the impurity diffusion area 66; an inter-layered insulation film 72, and the like. Like the plate electrode 67, obviously, the contact plug 71 may also be formed by means of the method for forming a conductor, described in the first embodiment. A semiconductor device 73 having a structure shown in FIG. 26 is obtained by means of the processes described up to now.

As has been described above, according to the sixth embodiment, advantageous effect similar to those of the first to fifth embodiments described previously can be attained. In addition, the trench capacitor 68 provided with the plate electrode 67 having a three-dimensional complicated shape can also be efficiently and easily formed. As a result, the semiconductor device 73 provided with the trench capacitor 68 can be efficiently and easily manufactured. Such a semiconductor device 73 can be manufactured inexpensively because productivity is good and the manufacturing process can be simplified.

### Seventh Embodiment

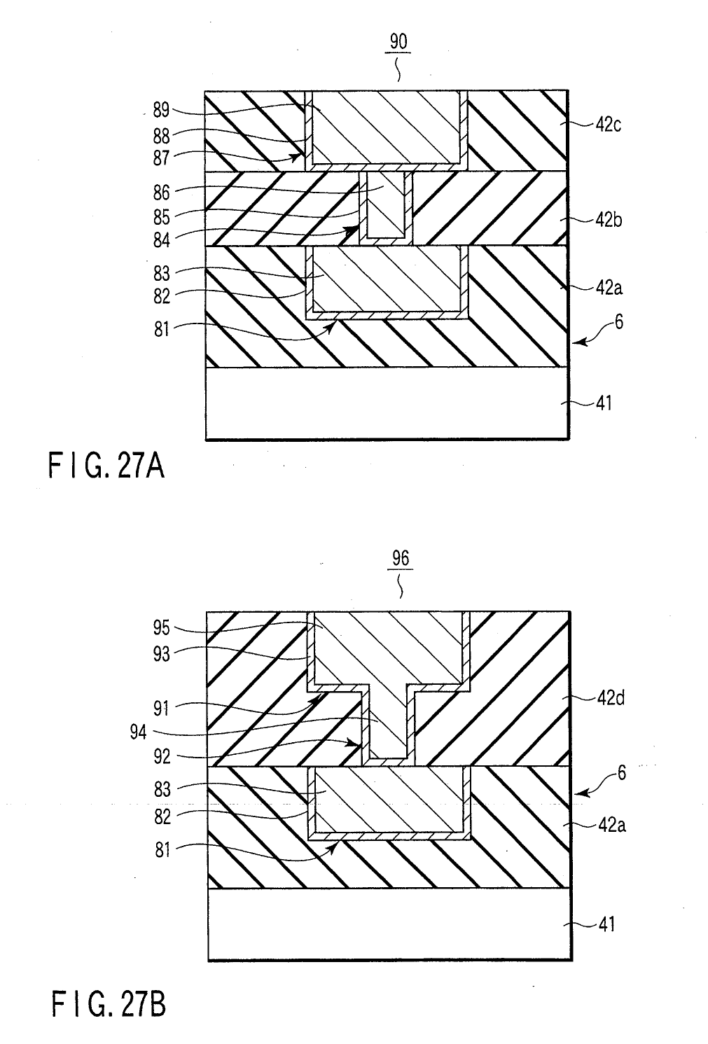

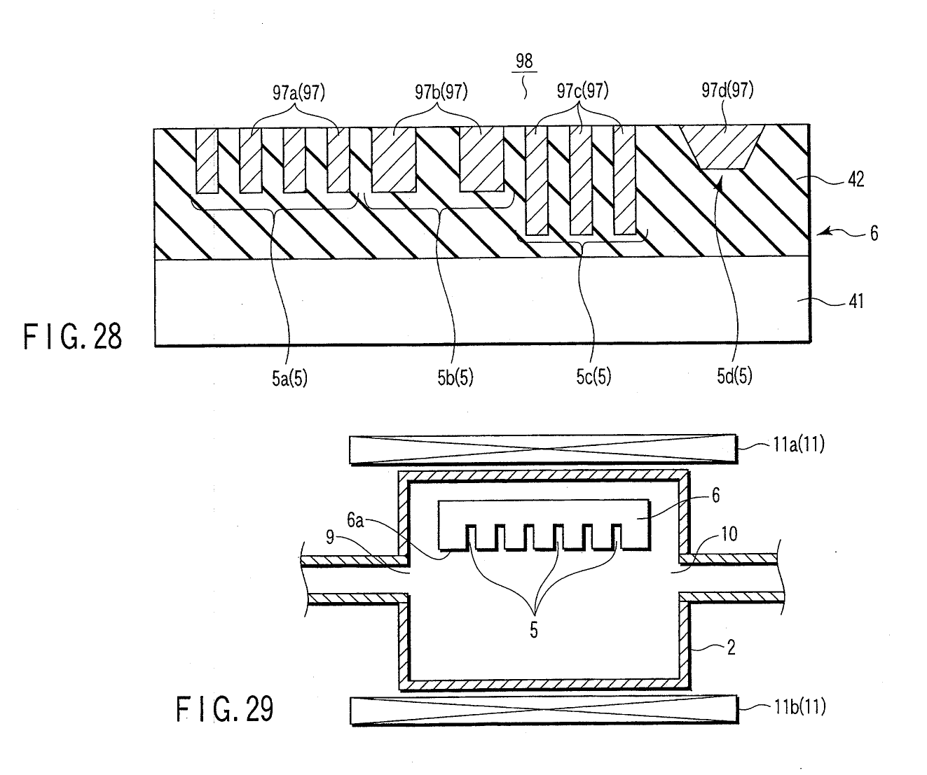

Now, a seventh embodiment according to the present invention will be described with reference to FIGS. 27A to 28. The same constituent elements as those in the first to sixth embodiments described previously are designated by the same reference numbers. A detailed description thereof is omitted here. In the present embodiment as well, as in the sixth embodiment described previously, a description will be given with respect to a technique of manufacturing semiconductor devices by using the method for forming a conductor, described in the first embodiment. However, in the present embodiment, unlike the sixth embodiment, a multi-layered wiring structure is formed using the method for forming a conductor, described previously.

First, a description will be given with respect to a case of forming a multi-layered wiring structure provided with an upper-layer wire and having a so-called single damascene structure in which a wire and a plug are formed independently, as shown in FIG. 27A.

First, on a substrate main body 41 of a silicon wafer 6, an inter-layered insulation film 42a of a first layer is provided by means of a well known CVD technique. Then, a lower-layer wiring recess 81 for providing a wire 83 of the first layer serving as a lower-layer wire is formed in the inter-layered insulation film 42a of the first layer by means of a well known etching process. Then, a lower-layer wiring barrier metal film 82 and a Cu film 83 serving as a lower-layer wire are embedded in the lower-layer wire forming recess 81 by means of a well known CVD or CMP technique. In this manner, a wire 83 of the first layer serving as the lower-layer wire is provided in the inter-layered insulation film 42a of the first layer.

Then, on the inter-layered insulation film 42a of the first layer in which the lower-layer Cu wire 83 has been provided, an inter-layered insulation film 42b serving as a lower layer side is provided among the inter-layered insulation film of a second layer by means of a well known CVD technique. Then, a via hole 84 for providing a via plug 86 for obtaining conductivity between the lower-layer Cu wire 83 and an upper-layer wire 99 is formed in a lower-layer side inter-layered insulation film 42b of the second layer by means of the well known etching process. Then, by means of a technique such as the well known CVD technique, a barrier metal film 85 for a via plug is formed on the surface of the lower-layer side inter-layered insulation film 42b of the second layer including the inside surface of the via hole 84.

Further, a silicon wafer 6 having the barrier metal film 85 provided thereon is housed in the pressure-resistant reaction container 2. Thereafter, the method for forming a conductor described in the first embodiment is executed. At this time, in the case where the via plug 86 is formed of Cu, any of the processing conditions may be employed from among the second to fourth embodiments described previously. In this manner, a Cu film 86 serving as a via plug can be formed selectively and with almost no gap inside the fine via hole 84 with high aspect ratio and at the periphery of an opening thereof. After the process for forming the Cu film 86 is terminated, the silicon wafer 6 is taken out from the inside of the pressure-resistant reaction container 2, and then, the Cu film 86 and the barrier metal film 85 are embedded in the via hole 84 by means of a well known CMP process. In this manner, the Cu via plug 86 is provided in the lower-layer side inter-layered insulation film 42b of the second layer.

Then, on the lower-layer side inter-layered insulation film 42b of the second layer in which the Cu via plug 86 has been provided, an inter-layered insulation film 42c serving as an upper layer side is provided among the inter-layered insulation film of the second layer by means of the well known CVD technique. Then, an upper-layer wire forming recess 87 for providing an upper-layer wire 89 is formed in the upper-layer side inter-layered insulation film 42c of the second layer by means of a technique such as the well known etching process. Then, by means of a technique such as the well known CVD technique, a barrier metal film 88 for the upper-layer wire is formed on the upper-layer side inter-layered insulation film 42c of the second layer such as the inside surface of the upper-layer wire forming recess 87.

Then, a silicon wafer 6 having the barrier metal film 88 provided thereon is housed again in the pressure-resistant reaction container 2. Thereafter, the method for forming a conductor described in the first embodiment is executed. At this time, in the case where the upper-layer wire 89 is formed of Cu, as in the case where the Cu via plug 86 is formed, any of the processing conditions of the second to fourth embodiments described previously may be employed. In this manner, a Cu film 89 serving as an upper-layer wire can be formed selectively and with almost no gap inside a fine upper-layer wire forming recess 87 and at the periphery of an opening thereof. After the process for forming the Cu film 89 is terminated, the silicon wafer 6 is taken out again from the inside of the pressure-resistant reaction container 2, and then, the Cu film 89 and the barrier metal film 88 are embedded in the upper-layer wire forming recess 87 by means of a process such as the well known CMP process. In this manner, the wire 89 of the second layer formed independently of the Cu via plug 86 is provided in the upper-layer side inter-layered insulation film 42c of the second layer. In other words, the upper-layer Cu wire 89 having a so-called single damascene structure is provided in the upper-layer side inter-layered insulation film 42c of the second layer.

By means of the processes described above, as shown in FIG. 27A, a semiconductor device 90 is obtained as a device provided with upper and lower two-layered multi-layered wiring structure in which the upper-layer Cu wire 89 and the lower-layer Cu wire 83 having the single damascene structure are made conductive via the barrier metal films 85, 88 and the Cu via plug 86.

Next, a description will be given with respect to a case of forming a multi-layered wire structure provided with an upper-layered wire having a so-called dual damascene structure, in which a wire and a plug are integrally formed, as shown in FIG. 27B.

First, a lower-layer Cu wire 83 is provided in an inter-layered insulation film 42a of the first layer by the same process as in the case of manufacturing the semiconductor device 90 described previously.

Then, an inter-layered insulation film 42d of the second layer is provided, by means of the well known CVD technique, on the inter-layered insulation film 83a of the first layer in which the lower-layer Cu wire 83 has been provided. Then, an upper-layer wire forming recess 91 for providing an upper-layer wire, and a via hole 92 for providing a via plug for obtaining conductivity between the upper-layer wire and the lower-layer Cu wire 83, are internally formed in communication with each other in the inter-layered insulation film 42d of the second layer by means of a process such as a well known etching process. Then, by means of a technique such as a well known CVD technique, an upper-layer wire barrier metal film 93 is formed on the surface of the inter-layered insulation film 42d of the second layer such as the inside surface of the via hole 92.

Then, the silicon wafer 6 having the barrier metal film 93 provided thereon is housed in the pressure-resistant reaction container 2. Thereafter, the method for selectively forming a conductor, described in the first embodiment, is executed. At this time, in the case where the upper-layer wire and the via plug are formed of Cu, as in the case of manufacturing the semiconductor device 90 described previously, any of the processing conditions of the second to fourth embodiments may be employed. In this manner, a via plug and a Cu film serving as an upper-layer wire can be formed selectively and with almost no gap inside the fine via hole 92 with high aspect ratio and the upper-layer wire forming recess 91 and at the periphery of an opening of the upper-layer wire forming recess 91. After the process for forming the Cu film is terminated, the silicon wafer 6 is taken out from the inside of the pressure-resistant reaction container 2, and then, the Cu film and the barrier metal film 93 are embedded in the via hole 92 and the upper-layer wire forming recess 91 by means of a process such as the well known CMP process. In this manner, a wire 95 of the second layer integrally formed with a Cu via plug 94 is provided in the inter-layered insulation film 42d of the second layer. In other words, an upper-layer Cu wire 95 having the so-called dual damascene structure is provided in the inter-layered insulation film 42d of the second layer.

By means of the processes described above, as shown in FIG. 275, a semiconductor device 96 is obtained as a device provided with upper and lower two-layered multi-layered wire structure in which the upper-layer Cu wire 95 and the lower-layer Cu wire 83 having the dual damascene structure are made conductive via the barrier metal film 93 and the Cu via plug 94.

Next, a description will be given with respect to a case of collectively providing conductors in a plurality of recesses 5 of which at least one of shape, depth, width, and aspect ratio is different from each other, as shown in FIG. 28.

First, by means of the process similar to the case of manufacturing the semiconductor devices 90, 96 described previously, an inter-layered insulation film 42 is provided by means of a well known CVD technique, on the substrate main body 41 of the silicon wafer 6. Then, first to fourth wire forming recesses 5a to 5d for providing first to fourth wires 97a to 97d are formed at a plurality of sites in the inter-layered insulation film 42 by means of a well known etching process. As shown in FIG. 28, the second wire forming recesses 5b are equal to the first wire forming recesses 5a in depth, but are wider and smaller in aspect ratio than the first wire forming recesses 5a. In addition, the third wire forming recesses 5c are equal to the first wire forming recesses 5a in depth, but are deeper and larger in aspect ratio than the first wire forming recesses 5a. Further, the fourth wire forming recess 5d is shallower, wider at an opening and a bottom part, and smaller in aspect ratio than the first wire forming recesses 5a. In addition, the first to third wire forming recesses 5a to 5c are formed in sectional rectangular shapes, whereas the fourth wire forming recess 5d is formed in an inverted trapezoidal shape such that the sectional shape is wider in opening than the bottom part.

Then, a silicon wafer 6 on which the first to fourth wire forming recesses 5a to 5d have been formed is housed in the pressure-resistant reaction container 2. Thereafter, the method for selectively forming a conductor, described in the first embodiment, is executed. At this time, in the case where the first to fourth wires 97a to 97d are formed of Cu, any of the processing conditions of the second to fourth embodiments may be employed as in the case of manufacturing the semiconductor devices 90, 96 described previously. In this manner, Cu films 97 can be collectively formed selectively and with almost no gap inside a plurality of recesses 5a to 5d of which at least one of shape, depth, width, and aspect ratio is different from each other and at the periphery of an opening thereof. After the process for forming the Cu film 97 is terminated, the silicon wafer 6 is taken out from the inside of the pressure-resistant reaction container 2, and then, the Cu film and the barrier metal film 93 are embedded in each of recesses 5a to 5d by means of the well known CMP process.

By means of the processes described above, as shown in FIG. 28, a semiconductor device 98 is obtained as a device provided with the first to fourth wires 97a to 97d of which at least one of shape, depth, width, and aspect ratio is different from each other.

As has been described above, according to the seventh embodiment, advantageous effect similar to those of the first to sixth embodiments described previously can be obtained. In other words, the semiconductor devices 90, 96 can be obtained as devices having a fine multi-layered wire structure of about 100 nm or less in size. In addition, conductors 97 can be collectively provided in a plurality of fine recesses 5 of which at least one of shape, depth, width, and aspect ratio is different from each other. Therefore, according to the present embodiment, the semiconductor devices 90, 96, 98 formed in a fine complicated shape in nano size level can be efficiently and easily manufactured. Like the upper-layer Cu wires 89, 95 and the Cu via plugs 86, 94, obviously, the lower-layer Cu wire 83 may be formed by means of the method for forming a conductor described in the first embodiment.

### Eighth Embodiment

Now, an eighth embodiment according to the present invention will be described with reference to FIG. 29.

The same constituent elements in the first to seventh embodiments described previously are designated by the same reference numbers. A detailed description thereof is omitted here. The present embodiment is different from the first embodiment described previously only in terms of posture of a processing target disposed inside a reaction container, and is similar to the first embodiment in the other aspects. Hereinafter, a brief description will be given.

As shown in FIG. 29, in the present embodiment, a substrate 6 serving as a processing target is disposed inside the pressure-resistant reaction container 2 in a posture such that a surface 6a thereof is oriented downwardly. At this time, more preferably, the surface 6a of the substrate 6 is oriented vertically downwardly. In this manner, even in the case where a mixture consisting of an auxiliary solvent 21 and a supercritical CO₂ fluid 8 is separated by gravity, the supercritical fluid can be preferentially brought into contact with the surface 6a of the substrate 6 and the interior face of the recesses 5. Characteristics of the “face down” method will be described more specifically.

In general, as the supercritical fluid is a compressive, high-density fluid, it has a characteristic of easily causing heat convention. For this reason, if the supercritical fluid in the pressure-resistant reaction container 2 is heated, a thermal layer of the supercritical fluid becomes present on an upper side inside the pressure-resistant reaction container 2, similarly to, for example, heated indoor air rising from a lower side to an upper side. Simultaneously, as the supercritical fluid is made to flow in a mainly vertical direction, from the lower side to the upper side of the pressure-resistant reaction container 2, uncontrollable rocking, turbulence and the like are reduced and a conductor forming process becomes stable. Therefore, if the substrate 6 is oriented on the upper side in the pressure-resistant reaction container 2, in a posture that the surface 6a serving as a deposition surface on which the conductor 33 is deposited faces toward the lower side (downwardly in the vertical direction), and the supercritical fluid in the pressure-resistant reaction container 2 is heated, the heating efficiency of the substrate 6 is enhanced as a hot layer of the supercritical fluid is stably and uniformly brought into contact, with priority, with the surface (deposition surface) 6a of the substrate 6 and each of the recesses 5. As a result, as the precipitation reaction of the conductor 33 occurs efficiently and stably, the conductor 33 can be provided efficiently and stable, in each of the recesses 5 or on the deposition surface 6a.

In addition, as the supercritical fluid is a high-density fluid as explained above, concentration of the raw material is high. For this reason, a reaction of generating particles may proceed due to tiny irregularity of the density in the conductor forming process. If particles are generated in the conductor forming process, the quality of the conductor 33 may be deteriorated at high likelihood. To prevent this preliminarily, too, the substrate 6 should preferably be disposed in the pressure-resistant reaction container 2 while the deposition surface 6a faces downwardly. Even if particles are generated, possibility that the particles may be left on the deposition surface 6a or in each of the recesses 5 can be substantially prevented, by arranging the substrate 6 in this posture. As a result, the conductor 33 of uniform and good quality can be formed on the deposition surface 6a and in each of the recesses 5.

As has been described above, according to the eighth embodiment, advantageous effect similar to those of the first to seventh embodiments described previously can be attained. In particular, in the case where the auxiliary solvent 21 and the supercritical CO₂ fluid 8 are used as a mixture, the substrate 6 is disposed inside the pressure-resistant reaction container 2 in a posture such that the surface 6a on which the recesses 5 are formed is oriented downwardly as in the present embodiment, whereby the conductor 33 can be formed more efficiently inside the recesses 5.

In the present embodiment as well, as in the first embodiment described previously, it is preferable that the substrate 6 be disposed at a position which is not on a straight line connecting a supply port 9 and a discharge port 10. In the first embodiment, as described previously, the substrate 6 is disposed inside the pressure-resistant reaction container 2 in a posture such that the surface 6a on which the recesses 5 are formed is oriented upwardly, as described previously, and thus, it is preferable that the substrate 6 be disposed so that the surface 6a there is positioned lower than the straight line connecting the supply port 9 and the discharge port 10. In this manner, a metal compound 7, auxiliary solvent 21, supercritical CO₂ fluid 8 and the like serving as materials for a conductor 33 can be efficiently supplied to the surface 6a of the substrate 6 or the interior face of the recesses 5 without interrupting the flow of the supercritical fluid 8 at the inside of the pressure-resistant reaction container 2 and while a capacity of a space above the surface 6a of the substrate 6 is sufficiently secured.

In contrast, in the present embodiment, as described previously, the substrate 6 is disposed inside the pressure-resistant reaction container 2 in a posture such that the surface 6a on which the recesses 5 are formed is oriented downwardly, and thus, it is preferable that the substrate 6 be disposed so that the surface 6a thereof is positioned above the straight line connecting the supply port 9 and the discharge port 10. In this manner, as in the first embodiment, a metal compound 7, auxiliary solvent 21, supercritical CO₂ fluid 8 and the like serving as materials for a conductor 33 can be efficiently supplied to the surface 6a of the substrate 6 or the interior face of the recesses 5 without interrupting the flow of the supercritical fluid 8 at the inside of the pressure-resistant reaction container 2 and while a capacity of a space below the surface 6a of the substrate 6 is sufficiently secured.

The apparatus for forming a conductor, the method for forming a conductor, and the method for manufacturing a semiconductor device, according to the present invention, are not limited to the first to eighth embodiments described previously. The present invention can be carried out without departing from the scope thereof by changing part of their construction or manufacturing processes to a variety of settings or by using a variety of settings in proper combination.

For example, in the first to fourth embodiments, the most expected Cu thin film 33 was formed as a conductor provided in the recesses 5. In addition, in the fifth embodiment, a ruthenium thin film 51 studied as a so-called glue film was formed as a conductor provided in the recesses 5. In addition, in the sixth and seventh embodiments, Cu thin films 67, 86, 89, 94, 95, and 97a to 97d were formed as conductors provided in recesses 62, 84, 87, 94, 91, and 5a to 5d. However, the conductors provided in recesses 5, 62, 84, 87, 94, 91, and 5a to 5d are not limited to the Ru thin film 51 or the Cu thin films 67, 86, 89, 94, 95, and 97a to 97d. The conductors provided in recesses 5, 62, 84, 87, 94, 91, and 5a to 5d may be conductors consisting essentially of a metal belonging to a platinum group other than ruthenium, for example. Specifically, the conductor consisting essentially of platinum (Pt), palladium (Pd), iridium (Ir), rhodium (Rh), or osmium (Os) can be provided in recesses 5, 62, 84, 87, 94, 91, and 5a to 5d according to the process for selectively forming a conductor according to the present invention.

In addition, an organic metal complex (precursor) including Cu 32 is not limited to diisobutyryl methanate copper (Cu(C₇H₁₅O₂)₂; Cu(dibm)₂)₇ described previously. As an organic metal complex including Cu 32, in addition to the diisobutyryl methanate copper 7, for example, there can be used hexafluoroacetyl acetonate copper (Cu(C₅HF₆O₂)₂; Cu(hfac)₂), Cu⁺²(hexafluoroacetyl acetonate)₂, Cu⁺²(acetyl acetonate)₂, Cu⁺²(2,2,6,6-tetramethyl-3,5-heptadione)₂, or the like. Even if these organic metal complexes are used, advantageous effect similar to those of the first to fourth, sixth and seventh embodiments can be attained. Similarly, the organic metal complex including ruthenium is not limited to the cyclopentadienyl ruthenium (Ru(C₅H₅)₂; RuCp₂) described previously. As an organic metal complex including ruthenium, in addition to cyclopentadienyl ruthenium, for example, there can be used an organic Ru compound or an oxygen-containing Ru complex such as RuCpMe, Ru(C₅HF₆O₂)₂; Ru(C₁₁H₁₉O₂)₃. By using these organic metal complexes, advantageous effect similar to that of the fifth embodiment can be obtained. In addition, in the metal compound (organic metal complex) including a metal serving as a essential component of these conductors, a phase (state) before processing does not always need to be a solid phase (solid). The phase (state) before processing of a metal compound including a metal serving as an essential component of the conductors may be a liquid phase (liquid).

In addition, the conductors provided in recesses 5, 62, 84, 87, 94, 91, and 5a to 5d are not always limited to a metal simplex made of a single metal such as ruthenium or copper. For example, the conductors provided in recesses 5, 62, 84, 87, 94, 91, and 5a to 5d may be an alloy made of two or more metals. The conductors provided in the recesses 5 may include at least one metal and may have conductivity. For example, in the method for selectively forming a conductor according to the present invention, an organic metal complex serving as a metal compound including copper and an organic metal complex serving as a metal compound including aluminum are dissolved in carbon dioxide of a supercritical fluid. By so doing, it is possible to provide an alloy made of copper and aluminum in the recesses 5.

Further, a material for the supercritical fluid is not limited to carbon dioxide. As other materials for the supercritical fluid, for example, there can be exemplified ethane (C₂H₆), dinitrogen monoxide (N₂O), butane (C₃H₈), ammonia (NH₃), hexane (C₆H₁₄), methanol (CH₃OH), ethanol (C₂H₅OH), and water (H₂O). Among these materials, ethane (C₂H₆) is about 32° C. in critical temperature at which a supercritical fluid is obtained and is about 4.9 MPa in critical pressure. In addition, dinitrogen monoxide (N₂O) is about 36° C. in critical temperature at which a supercritical fluid is obtained and is about 7.2 MPa in critical pressure. In other words, ethane (C₂H₆) and dinitrogen monoxide (N₂O) are materials that are easily handled like carbon dioxide.

The quantity of diisobutyryl methanate copper 7 dissolved in the supercritical CO₂ fluid 8 may not be in an over-saturated state described previously. According to a desired precipitation velocity of Cu 32, the quantity of the diisobutyryl methanate copper 7a dissolved in the supercritical CO₂ fluid 8 may be set in a sub-saturated or saturated state.

In addition, hydrogen 31 serving as a substance for promoting precipitation of Cu 32 does not always need to be mixed in the supercritical CO₂ fluid 8. Instead of mixing hydrogen 31 in the supercritical CO₂ fluid 8, as described in the first embodiment, at least one of the temperature and pressure of the atmosphere in the pressure-resistant reaction container 2 is changed and made non-uniform, whereby a fluctuation may be caused to occur in the density of the supercritical CO₂ fluid 8. With such a method, the density of the supercritical CO₂ fluid 8 is made non-uniform, and a density fluctuation is caused to occur, making it possible to promote precipitation of Cu 32 from the diisobutyryl methanate copper 7a. Alternatively, such a method and mixture of hydrogen 31 into the supercritical CO₂ fluid 8 may be used together.

Further, the mixing of hydrogen 31 into the supercritical CO₂ fluid 8 does not always need to be carried out prior to dissolving the diisobutyryl methanate copper 7 dissolved in acetone 21 in the supercritical CO₂ fluid 8. The mixing of hydrogen 31 into the supercritical CO₂ fluid 8 may be carried out at the same time as dissolving the diisobutyryl methanate copper 7 dissolved in acetone 21 in the supercritical CO₂ fluid 8, or alternatively, after dissolving the diisobutyryl methanate copper 7 dissolved in acetone 21 in the supercritical CO₂ fluid 8.

In addition, an applied example of the method for forming a conductor according to the present invention is not limited to the method for manufacturing a semiconductor device, described in the sixth and seventh embodiments. As another applied example of the method for selectively forming a conductor according to the present invention, there can be exemplified a method for manufacturing a high-density magnetic recording medium (nano-dot magnetic recording medium) or nonlinear optical element. Alternatively, the method for selectively forming a conductor according to the present invention, is obviously applicable to a process for forming a seed film made of conductors serving as a basis for wiring in recesses such as fine holes or grooves with high aspect ratio, in a process for forming fine wires inside a fine semiconductor element such as CMOS.

Further, although specific and detailed illustrative description is omitted, according to the experiment carried out by the inventors, it has been found possible to selectively providing conductors inside very fine recesses with a width of about 10 nm or less as well as recesses with a width of about 100 nm, as in the second to fifth embodiments, by using the method for selectively forming a conductor according to the present invention. In other words, according to the method for selectively forming a conductor according to the present invention, it has been found possible to embed conductors efficiently and easily with almost no gap, inside recesses with extreme fineness and high aspect ratio, which are almost impossible to embed with no gap by means of the conventional CVD technique or PVD technique. In other words, it has been found that the method for selectively forming a conductor according to the present invention is well applicable to a process for manufacturing a variety of elements and devices requiring conductors having a fine complicated structure or shape.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1-27. (canceled)

28. A conductor forming method comprising:
to a processing target on a surface of which at least one recess in which a conductor to be provided is formed, continuously supplying a supercritical fluid dissolved with a metal compound including a metal serving as a material for the conductor, and continuously eliminating from a periphery of the processing target the supercritical fluid that is not submitted for a process for providing the conductor in the recess, thereby adjusting an amount of the supercritical fluid around the processing target;
selectively introducing in the recess the metal compound dissolved in the supercritical fluid in contact with the surface of the processing target and aggregating in the recess the metal compound introduced into the recess to precipitate the metal from the metal compound; and
solidifying the metal precipitated in the recess, thereby providing the conductor in the recess.

29. The method according to claim 28, wherein an amount of the supercritical fluid at the periphery of the processing target is stabilized by adjusting a supply quantity of the supercritical fluid to the processing target and a discharge quantity of the supercritical fluid from the periphery of the processing target.

30. The method according to claim 28, wherein a concentration of the metal compound at the periphery of the processing target is stabilized by adjusting a supply quantity of the supercritical fluid to the processing target and a discharge quantity of the supercritical fluid from the periphery of the processing target.

31. The method according to claim 28, wherein a peripheral pressure of the processing target is stabilized by adjusting a supply quantity of the supercritical fluid to the processing target and a discharge quantity of the supercritical fluid from the periphery of the processing target.

32. The method according to claim 28, further comprising:
supplying to the processing target a supercritical fluid in which the metal compound is not dissolved, instead of the supercritical fluid in which the metal compound is dissolved, thereby adjusting a concentration of the metal compound at the periphery of the processing target.

33. The method according to claim 28, wherein carbon dioxide is used as the material for the supercritical fluid.

34. The method according to claim 28, wherein a solid organic metal complex is supplied as the metal compound to the supercritical fluid.

35. The method according to claim 34, wherein a solid organic metal complex including copper is supplied as the solid organic metal complex to the supercritical fluid.

36. The method according to claim 35, wherein a diisobutyryl methanate copper is supplied to the supercritical fluid as the solid organic metal compound including copper.

37. The method according to claim 28, wherein a fluorine-free metal compound is supplied as the metal compound to the supercritical fluid.

38. The method according to claim 28, further comprising:
using a solid metal compound as the metal compound and, after dissolving the solid metal compound in an auxiliary solvent for easily dissolving the compound in the supercritical fluid, supplying the solid metal compound dissolved in the auxiliary solvent to the supercritical fluid.

39. The method according to claim 38, wherein a diisobutyryl methanate copper is used as the solid metal compound and, after the diisobutyryl methanate copper is dissolved in acetone as an auxiliary solvent, the diisobutyryl methanate copper dissolved in the acetone is supplied in supercritical fluid carbon dioxide.

40. The method according to claim 28, further comprising:
further supplying into the supercritical fluid a reaction promoter for promoting precipitation of the metal from the metal compound.

41. The method according to claim 40, wherein after the reaction promoter is supplied into the supercritical fluid, the metal compound is supplied into the supercritical fluid.

42. The method according to claim 40, wherein a concentration of the reaction promoter at the periphery of the processing target is stabilized by adjusting a supply quantity of the reaction promoter into the supercritical fluid and a discharge quantity of the supercritical fluid from the periphery of the processing target.

43. The method according to claim 40, wherein hydrogen is supplied as the reaction promoter into the supercritical fluid.

44. The method according to claim 28, wherein temperatures of the processing target and the periphery thereof are regulated to a temperature at which the process is easily progressed.

45. The method according to claim 28, wherein while a temperature of the material for the supercritical fluid is regulated to a temperature at which the material can exist in a state of a supercritical fluid, the material is supplied to the processing target.

46. The method according to claim 28, wherein a reaction of the metal compound precipitating from the supercritical fluid is restricted until the supercritical fluid reaches the periphery of the processing target.

47. The method according to claim 46, wherein a temperature of the supercritical fluid is regulated to a temperature at which the precipitation reaction is restricted, until the supercritical fluid reaches the periphery of the processing target.

48. The method according to claim 28, wherein the supercritical fluid is preheated to a predetermined temperature prior to introducing the fluid into the reaction container.

49. The method according to claim 48, wherein the predetermined temperature is set to be equal to or lower than a processing temperature at the time of providing the conductor in the recess inside the reaction container.

50. The method according to claim 28, wherein the processing target is disposed inside the reaction container in a posture such that a surface thereof on which the recess has been formed is oriented downwardly.

51. The method according to claim 28, wherein in a flow of the supercritical fluid flowing in the periphery of the processing target, a pressure at a downstream side of the processing target is made smaller than that at an upstream side of the processing target, thereby eliminating the supercritical fluid from the periphery of the processing target.

52. The method according to claim 28, wherein the conductors are collectively provided in a plurality of the recesses of which at least one of a shape, depth, width, and aspect ratio is different from each other.

53. A manufacturing method for a semiconductor device comprising:
to a semiconductor substrate on which at least one recess, in which a conductor is provided, is formed on a surface of at least one of a substrate main body and an insulation film provided above the substrate main body, continuously supplying a supercritical fluid dissolved with a metal compound including a metal serving as a material for the conductor and continuously eliminating from a periphery of the semiconductor substrate the supercritical fluid that is not submitted for a process for providing the conductor in the recess, thereby adjusting an amount of the supercritical fluid at the periphery of the semiconductor substrate;
selectively introducing in the recess the metal compound dissolved in the supercritical fluid in contact with a surface of the semiconductor substrate and aggregating in the recess the metal compound introduced in the recess to precipitate the metal from the metal compound; and
providing the conductor in the recess by solidifying the metal precipitated in the recess.

54. The method according to claim 53, wherein the conductor is provided in the recess formed at a surface layer part of the substrate main body and an embedding electrode of a trench capacitor is formed at the surface layer part of the substrate main body.

55. The method according to claim 53, wherein the conductor is provided in the recess formed in the insulation film provided above the substrate main body, and at least one of a wire and a plug is formed in the insulation film.
